(19) United States
(12) Patent Application Publication
(10) Pub. No.: US 2025/0117527 A1
(43) Pub. Date: Apr. 10, 2025

(54) AUTOMATED DESIGN OBJECT LABELING VIA MACHINE LEARNING MODELS

(71) Applicant: AUTODESK, INC., San Francisco, CA (US)

(72) Inventors: George William FITZMAURICE, Toronto (CA); Jo Karel VERMEULEN, East York (CA); Justin Frank MATEJKA, Newmarket (CA)

(21) Appl. No.: 18/748,982

(22) Filed: Jun. 20, 2024

Related U.S. Application Data
(60) Provisional application No. 63/588,271, filed on Oct. 5, 2023.

(51) Int. Cl. G06F 30/10; G06F 30/27

(52) U.S. Cl. CPC G06F 30/10; G06F 30/27

(57) ABSTRACT

In various embodiments, a computer-implemented method for displaying object information associated with a computer-aided design, the method comprising displaying a design space that includes a plurality of design objects, generating a prompt that includes a set of object identifiers corresponding to a first set of design objects included in the plurality of design objects and a first query for a set of object labels corresponding to the first set of design objects, transmitting the prompt to at least one trained machine learning (ML) model for processing, receiving, from the at least one trained ML model, a first ML response that includes the set of object labels corresponding to the first set of design objects, and displaying the set of object labels within the design space.

### CROSS-REFERENCE TO RELATED APPLICATIONS

This application claims priority benefit of the United States Provisional Patent Application titled, “TECHNIQUES FOR PROVIDING NATURAL LANGUAGE ASSISTANCE USING OBJECT/PROMPT TIPS,” filed on Oct. 5, 2023 and having Ser. No. 63/588,271. The subject matter of this related application is hereby incorporated herein by reference.

### BACKGROUND

### Field of the Various Embodiments

The various embodiments relate generally to computer-aided design and artificial intelligence and, more specifically, to automated design object labeling via machine learning models.

### Description of the Related Art

Design exploration for three-dimensional (3D) objects via computer-aided design (CAD) applications generally refers to a phase of a design process during which an initial designer experiments with using various 3D design objects within an overall 3D design. During this design phase, the initial designer usually generates and modifies numerous 3D design objects to generate an overall 3D design, such as an assembly that includes multiple design objects and possibly several sub-assembly objects as well. Notably, each sub-assembly object can include a large number of part objects, and each part object can include a large number of element objects (such as geometric primitives). Accordingly, for relatively complex assemblies, the number of such design objects can number in the hundreds or thousands. The initial designer oftentimes does not provide labels and/or additional information for the various design objects in a given assembly design because the initial designer typically has expertise or experience with the particular assembly being designed. In addition, conventional CAD applications do not include any tools that can automatically label and/or provide additional information describing the various design objects of an assembly design.

One drawback of the above design approach and the use of conventional CAD application in designing assemblies is that a subsequent designer that does not have expertise or experience in the particular assembly being designed can have difficulty reviewing and/or contributing to the design. In particular, a subsequent designer can have difficulty understanding the various design objects of an assembly, such as the types of components the design objects represent and the CAD commands that were used to generate and/or modify the design objects in the assembly. To gain knowledge and understanding of the particular assembly being designed, the subsequent designer can manually study and research the particular assembly and try to determine the design history underlying the particular assembly. However, this type of research and study usually requires significant effort and time on the part of the subsequent designer. Consequently, subsequent designers typically proceed with reviewing and/or contributing to the assembly design without adequately understanding make-up of the assembly and the design choices made by the initial designer when designing and generating the assembly in the first place. Continuing the design process without adequately understanding the overall design can lead to misinformed decisions and negatively impact the overall quality of the final assembly design and reduce the efficiency of the overall design process.

As the foregoing illustrates, what is needed in the art are more effective techniques for understanding the design objects included in assembly designs.

### SUMMARY

In various embodiments, a computer-implemented method for displaying object information associated with a computer-aided design, the method comprising displaying a design space that includes a plurality of design objects, generating a prompt that includes a set of object identifiers corresponding to a first set of design objects included in the plurality of design objects and a first query for a set of object labels corresponding to the first set of design objects, transmitting the prompt to at least one trained machine learning (ML) model for processing, receiving, from the at least one trained ML model, a first ML response that includes the set of object labels corresponding to the first set of design objects, and displaying the set of object labels within the design space.

At least one technical advantage of the disclosed techniques relative to the prior art is that the disclosed techniques can be used to automatically generate and display a wide variety of object information associated with one or more design objects included in an overall design (assembly) via one or more ML models. For each design object, the displayed object information can include an object label that identifies a specific type of sub-assembly, part, or element that the design object represents, additional detailed information (including alternative geometries) for the design object, and/or a set of design application commands that were executed to generate and/or modify the design object. As such, the disclosed techniques instantly label and provide further insight into the different design objects of the assembly. By automatically providing different levels of object information (labels, additional details, and associated commands) for the design objects of an assembly, the disclosed techniques allow a user to quickly and easily gain different levels of understanding about the design objects of the assembly. In addition, the disclosed techniques allow a user without any prior exposure to or experience with a particular assembly to better and more quickly understand the assembly and the objects making up the assembly, thereby enabling the user to review and/or contribute to a design project involving the assembly more readily and easily. These technical advantages provide one or more technological advancements over prior art approaches.

### BRIEF DESCRIPTION OF THE DRAWINGS

So that the manner in which the above recited features of the various embodiments can be understood in detail, a more particular description of the inventive concepts, briefly summarized above, may be had by reference to various embodiments, some of which are illustrated in the appended drawings. It is to be noted, however, that the appended drawings illustrate only typical embodiments of the inventive concepts and are therefore not to be considered limiting of scope in any way, and that there are other equally effective embodiments.

FIG. 1 is a conceptual illustration of a system configured to implement one or more aspects of the various embodiments;

FIG. 2 is a more detailed illustration of the design application of FIG. 1, according to various embodiments;

FIG. 3 is a conceptual diagram of one of the assembly tables of FIG. 2, according to various embodiments;

FIG. 4 is an exemplar illustration of a bike assembly shown at a first zoom level within the design space of FIG. 2, according to various embodiments;

FIG. 5 is an exemplar illustration of the bike assembly of FIG. 4 with sub-assembly labels, according to various embodiments;

FIG. 6 is an exemplar illustration of the bike assembly of FIG. 4 with sub-assembly details, according to various embodiments;

FIG. 7 is an exemplar illustration of the bike assembly of FIG. 4 with sub-assembly commands, according to various embodiments;

FIG. 8 is an exemplar illustration of the bike assembly shown at a second zoom level within the design space of FIG. 2, according to various embodiments;

FIG. 9 is an exemplar illustration of the bike assembly of FIG. 8 with part labels, according to various embodiments;

FIG. 10 is an exemplar illustration of the bike assembly of FIG. 8 with part details, according to various embodiments;

FIG. 11 is an exemplar illustration of the bike assembly of FIG. 8 with part commands, according to various embodiments;

FIG. 12 is an exemplar illustration of the bike assembly of FIG. 8 with a color key chart, according to various embodiments;

FIG. 13 is an exemplar illustration of a portion of a bike assembly shown at a third zoom level within the design space of FIG. 2, according to various embodiments;

FIG. 14 is an exemplar illustration of the portion of the bike assembly of FIG. 13 with element labels, according to various embodiments;

FIG. 15 is an exemplar illustration of the portion of the bike assembly of FIG. 13 with element details, according to various embodiments;

FIG. 16 is an exemplar illustration of the portion of the bike assembly of FIG. 13 with element commands, according to various embodiments;

FIGS. 17A-B set forth a flow diagram of method steps for automatically retrieving and displaying object information for design objects within an overall design, according to various embodiments; and

FIG. 18 depicts one architecture of a system within which one or more aspects of the various embodiments may be implemented.

### DETAILED DESCRIPTION

In the following description, numerous specific details are set forth to provide a more thorough understanding of the various embodiments. However, it will be apparent to one skilled in the art that the inventive concepts may be practiced without one or more of these specific details. For explanatory purposes, multiple instances of like objects are symbolized with reference numbers identifying the object and parenthetical numbers(s) identifying the instance where needed.

### System Overview

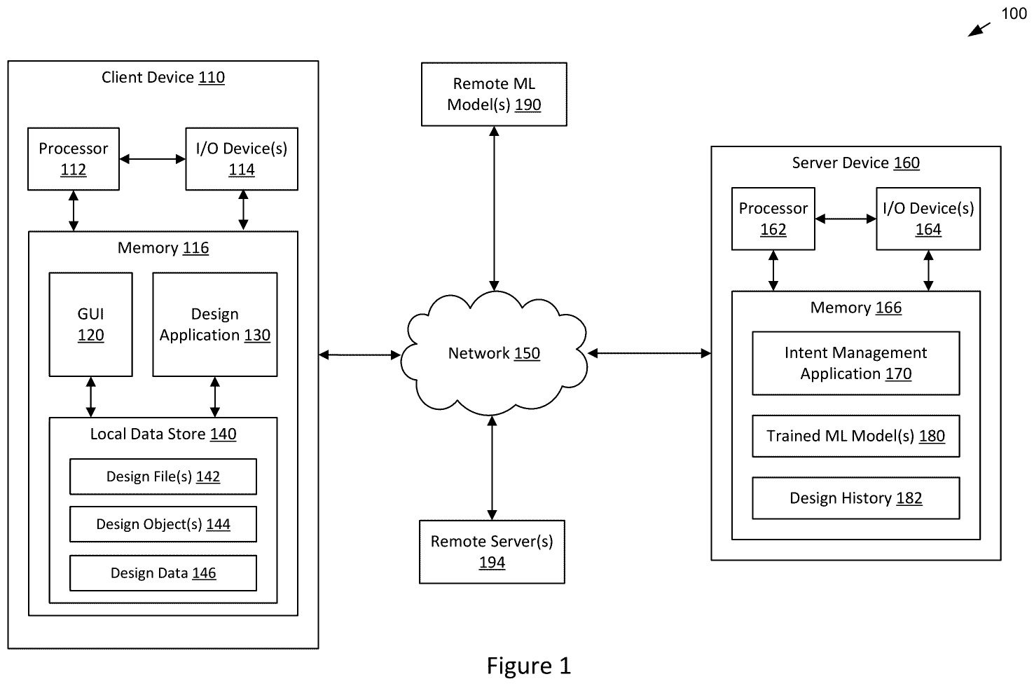

FIG. 1 is a conceptual illustration of a system 100 configured to implement one or more aspects of the various embodiments. As shown, in some embodiments, the system 100 includes, without limitation, a client device 110, a server device 160, one or more remote machine learning (ML) models 190, and one or more remote servers 194.

The client device 110 includes, without limitation, a processor 112, one or more input/output (I/O) devices 114, and a memory 116. The memory 116 includes, without limitation, a graphical user interface (GUI) 120, a design application 130, and a local data store 140. The local data store 140 includes, without limitation, one or more design files 142, one or more design objects 144, and/or design data 146. The server device 160 includes, without limitation, a processor 162, one or more I/O devices 164, and a memory 166. The memory 166 includes, without limitation, an intent management application 170, one or more trained ML models 180, and design history 182. In some other embodiments, the system 100 can include any number and/or types of other client devices, server devices, remote ML models, databases, or any combination thereof.

Any number of the components of the system 100 can be distributed across multiple geographic locations or implemented in one or more cloud computing environments (e.g., encapsulated shared resources, software, data) in any combination. In some embodiments, the client device 110 and/or zero or more other client devices (not shown) can be implemented as one or more compute instances in a cloud computing environment, implemented as part of any other distributed computing environment, or implemented in a stand-alone fashion. In various embodiments, the client device 110 can be integrated with any number and/or types of other devices (e.g., one or more other compute instances and/or a display device) into a user device. Some examples of user devices include, without limitation, desktop computers, laptops, smartphones, and tablets.

In general, the client device 110 is configured to implement one or more software applications. For explanatory purposes only, each software application is described as residing in the memory 116 of the client device 110 and executing on the processor 112 of the client device 110. In some embodiments, any number of instances of any number of software applications can reside in the memory 116 and any number of other memories associated with any number of other compute instances and execute on the processor 112 of the client device 110 and any number of other processors associated with any number of other compute instances in any combination. In the same or other embodiments, the functionality of any number of software applications can be distributed across any number of other software applications that reside in the memory 116 and any number of other memories associated with any number of other compute instances and execute on the processor 112 and any number of other processors associated with any number of other compute instances in any combination. Further, subsets of the functionality of multiple software applications can be consolidated into a single software application.

In particular, the client device 110 is configured to implement a design application 130 to generate one or more two-dimensional (2D) or 3D designs, such as 2D floorplan designs and/or 3D designs for 3D objects. In some embodiments, the design application 130 causes one or more ML models 180, 190 to synthesize designs for a 3D object based on any number of goals and constraints. The design application 130 then presents the designs as one or more design objects 144 to a user in the context of a design space. In some embodiments, the user can explore and modify the design objects 144 via the GUI 120.

In various embodiments, the processor 112 can be any instruction execution system, apparatus, or device capable of executing instructions. For example, the processor 112 can comprise general-purpose processors (such as a central processing unit), special-purpose processors (such as a graphics processing unit), application-specific processors, field-programmable gate arrays, or other programmable logic device, discrete gate or transistor logic, discrete hardware components, or any combination of different processing units. In some embodiments, the processor 112 is a programmable processor that executes program instructions to manipulate input data. In some embodiments, the processor 112 can include any number of processing cores, memories, and other modules for facilitating program execution.

The input/output (I/O) devices 114 include devices configured to receive input, including, for example, a keyboard, a mouse, trackball, and so forth. In some embodiments, the I/O devices 114 also includes devices configured to provide output, including, for example, a display device, a speaker, and so forth. For example, an input device can enable a user to control a cursor displayed on an output device for selecting various elements displayed on the output device 114. Additionally or alternatively, the I/O devices 114 may further include devices configured to both receive and provide input and output, respectively, including, for example, a touchscreen, a universal serial bus (USB) port, and so forth.

The memory 116 includes a memory module, or collection of memory modules. In some embodiments, the memory 116 can include a variety of computer-readable media selected for their size, relative performance, or other capabilities: volatile and/or non-volatile media, removable and/or non-removable media, etc. The memory 116 can include cache, random access memory (RAM), storage, etc. The memory 116 can include one or more discrete memory modules, such as dynamic RAM (DRAM) dual inline memory modules (DIMMs). Of course, various memory chips, bandwidths, and form factors may alternately be selected. The memory 116 stores content, such as software applications and data, for use by the processor 112. In some embodiments, a storage (not shown) supplements or replaces the memory 116. The storage can include any number and type of external memories that are accessible to the processor 112 of the client device 110. For example, and without limitation, the storage can include a Secure Digital (SD) Card, an external Flash memory, a portable compact disc read-only memory, an optical storage device, a magnetic storage device, or any suitable combination of the foregoing.

Non-volatile memory included in the memory 116 generally stores one or more application programs including the design application 130, and data (e.g., the design files 142, the design objects 144, and/or the design data 146 stored in the local data store 140) for processing by the processor 112. In various embodiments, the memory 116 can include non-volatile memory, such as optical drives, magnetic drives, flash drives, or other storage. In some embodiments, separate data stores, such as one or more external data stores connected via the network 150 (“cloud storage”) can supplement the memory 116. In various embodiments, the design application 130 within the memory 116 can be executed by the processor 112 to implement the overall functionality of the client device 110 to coordinate the operation of the system 100 as a whole.

In various embodiments, the memory 116 can include one or more modules for performing various functions or techniques described herein. In some embodiments, one or more of the modules and/or applications included in the memory 116 may be implemented locally on the client device 110, and/or may be implemented via a cloud-based architecture. For example, any of the modules and/or applications included in the memory 116 could be executed on a remote device (e.g., smartphone, a server system, a cloud computing platform, etc.) that communicates with the client device 110 via a network interface or an I/O devices interface.

The design application 130 resides in the memory 116 and executes on the processor 112 of the client device 110. The design application 130 interacts with a user via the GUI 120. In various embodiments, the design application 130 operates as a 2D or 3D design application to generate and modify an overall 2D or 3D design that includes one or more 2D or 3D design objects 144. The design application 130 interacts with a user via the GUI 120 to generate the one or more design objects 144 via direct user input (e.g., one or more tools of the design application 130 are used to generate 3D objects, wireframe geometries, meshes, etc.) or via separate devices (e.g., the trained ML models 180, the remote ML models 190, separate 3D design applications, etc.). When generating the one or more design objects 144 via separate devices, the design application 130 generates (based on user inputs) a prompt that effectively describes design-related intentions using one or more modalities (e.g., text, speech, images, etc.). The design application 130 then causes the one or more of the ML models 180, 190 to operate on the generated prompt to generate a relevant ML response, such as a relevant design object 144. The design application 130 receives the ML response (such as the design object 144) from the one or more ML models 180, 190 and displays the ML response (such as the design object 144) within the GUI 120. The user can select, via the GUI 120, the design object 144 for modification or use, such as incorporating the design object 144 into the larger overall 3D design (such as an assembly) displayed in the GUI 120.

The GUI 120 can be any type of user interface that allows users to interact with one or more software applications via any number and/or types of GUI elements. The GUI 120 can be displayed in any technically feasible fashion on any number and/or types of stand-alone display device, any number and/or types of display screens that are integrated into any number and/or types of user devices, or any combination thereof. The design application 130 can perform any number and/or types of operations to directly and/or indirectly display and monitor any number and/or types of interactive GUI elements and/or any number and/or types of non-interactive GUI elements within the GUI 120. In some embodiments, each interactive GUI element enables one or more types of user interactions that automatically trigger corresponding user events. Some examples of types of interactive GUI elements include, without limitation, scroll bars, buttons, text entry 300 boxes, drop-down lists, and sliders. In some embodiments, the design application 130 organizes GUI elements into one or more container GUI elements (e.g., panels and/or panes).

The local data store 140 is a part of storage in the client device 110 that stores one or more design objects 144 included in an overall 3D design, one or more design files 142 associated with the overall 3D design, and design data 146 associated with the overall 3D design. For example, an overall 3D design for an overall assembly (such as a bicycle) can include multiple stored design objects 144, including design objects 144 separately representing pedals, chain, saddle, and so forth. The design objects 144 of an overall 3D design (such as an assembly) can include one or more sub-assembly objects, one or more part objects, and one or more element objects. Each sub-assembly object comprises one or more part objects and each part object comprises one or more element objects (i.e., geometric primitives such as vertices, edges, faces, boundary representations, etc.). For example, the overall design can comprise a bike assembly that includes a frame sub-assembly, a controls sub-assembly, a drivetrain sub-assembly, etc. The frame sub-assembly can comprise a toptube part, downtube part, etc. The toptube part can comprise elements such as vertices, faces, etc.

In general, a design object includes, without limitation, one or more images, wireframe models, 2D or 3D geometries, and/or meshes for use in a 2D or 3D design, as well and any amount (including none) and/or types of associated metadata. As such, the design objects 144 can include geometries, textures, images, and/or other components that the design application 130 uses to generate an overall design. In some embodiments, the geometry of a given design object refers to any multi-dimensional model of a physical structure, including CAD models, meshes, and point clouds, as well as building layouts, circuit layouts, piping diagrams, free-body diagrams, and so forth. In some embodiments, the design application 130 stores multiple design objects 144 for a given overall 3D design (such as an assembly) and stores multiple iterations of a given target object that the ML models 180, 190 have iteratively modified. The design application 130 also generates and stores metadata for each design object 144 in the overall 3D design, such as an object ID that uniquely identifies the design object 144 within the overall 3D design.

The one or more design files 142 (e.g., component files, metadata, etc.) are associated with the overall 3D design. In some embodiments, a design file 142 comprises a container that stores the overall 3D design and all design objects 144 of the overall 3D design, including metadata (such as object IDs) associated with the overall 3D design and all design objects 144 of the overall 3D design. For example, a design file 142 can include all design objects 144 included in an overall assembly, including various sub-assembly objects, part objects, and element objects, as well as the metadata associated with each design object 144. In some embodiments, a design file 142 comprises a container that stores only a subset of design objects 144 of the overall 3D design, including metadata (such as object IDs) associated with the subset of design objects. For example, a design file 142 can include a subset of design objects 144 comprising element objects, as well as the metadata associated with each design object 144. Additionally or alternatively, as discussed below, the design files 142 can also be used to generate prompts for transmission to the one or more ML models 180, 190. For example, the design files 142 can include an overall assembly (i.e., all design objects 144 of the overall assembly), or only specific design objects 144 of the overall assembly, such as geometries (e.g., wireframes, meshes, etc.) for specific element objects. In other embodiments, the design files 142 can include images, videos, application states, audio recordings, and so forth.

In some embodiments, the design data 146 includes specific metadata that is parsed from the metadata of the design objects 144 of the overall 3D design, such as the unique object identifiers (IDs) for each design object 144. In further embodiments, the design data 146 includes design application commands associated with the overall 3D design comprising design application commands that were executed by the design application 130 to generate and/or modify the various design objects 144 of the overall 3D design. Additionally or alternatively, as discussed below, the design data 146 can also be used to generate prompts for transmission to the one or more ML models 180, 190.

The network 150 can be any technically feasible set of interconnected communication links, including a local area network (LAN), wide area network (WAN), the World Wide Web, or the Internet, among others. The network 150 enables communications between the client device 110 and other devices in network 150 via wired and/or wireless communications protocols, including Bluetooth, Bluetooth low energy (BLE), wireless local area network (WiFi), cellular protocols, satellite networks, and/or near-field communications (NFC).

The server device 160 is configured to communicate with the design application 130 to generate one or more ML responses in response to one or more received prompts. In operation, the server device 160 executes one or more ML models 180, 190 to process one or more prompts that is received from the design application 130 to determine object labels, object details, and/or object commands for a set of design objects 144. Once the selected ML models 180, 190 generate the one or more ML responses to the one or more prompts, the server device 160 transmits the one or more ML responses to the client device 110, where the generated one or more ML responses are usable by the design application 130.

In various embodiments, the processor 162 can be any instruction execution system, apparatus, or device capable of executing instructions. For example, the processor 162 could comprise a central processing unit (CPU), a digital signal processing unit (DSP), a microprocessor, an application-specific integrated circuit (ASIC), a neural processing unit (NPU), a graphics processing unit (GPU), a field-programmable gate array (FPGA), a controller, a microcontroller, a state machine, or any combination thereof. In some embodiments, the processor 162 is a programmable processor that executes program instructions to manipulate input data. In some embodiments, the processor 162 can include any number of processing cores, memories, and other modules for facilitating program execution.

The input/output (I/O) devices 164 include devices configured to receive input, including, for example, a keyboard, a mouse, and so forth. In some embodiments, the I/O devices 164 also includes devices configured to provide output, including, for example, a display device, a speaker, and so forth. Additionally or alternatively, the I/O devices 164 may further include devices configured to both receive and provide input and output, respectively, including, for example, a touchscreen, a universal serial bus (USB) port, and so forth.

The memory 166 includes a memory module, or collection of memory modules. In some embodiments, the memory 166 can include a variety of computer-readable media selected for their size, relative performance, or other capabilities: volatile and/or non-volatile media, removable and/or non-removable media, etc. The memory 166 can include cache, random access memory (RAM), storage, etc. The memory 166 can include one or more discrete memory modules, such as dynamic RAM (DRAM) dual inline memory modules (DIMMs). Of course, various memory chips, bandwidths, and form factors may alternately be selected. The memory 166 stores content, such as software applications and data, for use by the processor 162. In some embodiments, a storage (not shown) supplements or replaces the memory 166. The storage can include any number and type of external memories that are accessible to the processor 162 of the server device 160. For example, and without limitation, the storage can include a Secure Digital (SD) Card, an external Flash memory, a portable compact disc read-only memory, an optical storage device, a magnetic storage device, or any suitable combination of the foregoing.

Non-volatile memory included in the memory 166 generally stores one or more application programs including the intent management application 170 and the one or more trained ML models 180, and data (e.g., design history 182) for processing by the processor 112. In various embodiments, the memory 166 can include non-volatile memory, such as optical drives, magnetic drives, flash drives, or other storage. In some embodiments, separate data stores, such as one or more external data stores connected via the network 150 can supplement the memory 166. In various embodiments, the intent management application 170 and/or the one or more ML models 180 within the memory 166 can be executed by the processor 162 to implement the overall functionality of the server device 160 to coordinate the operation of the system 100 as a whole.

In various embodiments, the memory 166 can include one or more modules for performing various functions or techniques described herein. In some embodiments, one or more of the modules and/or applications included in the memory 166 may be implemented locally on the client device 110, server device 160, and/or may be implemented via a cloud-based architecture. For example, any of the modules and/or applications included in the memory 166 could be executed on a remote device (e.g., smartphone, a server system, a cloud computing platform, etc.) that communicates with the server device 160 via a network interface or an I/O devices interface. Additionally or alternatively, the intent management application 170 could be executed on the client device 110 and can communicate with the trained ML models 180 operating at the server device 160.

In various embodiments, the intent management application 170 receives a prompt from the design application 130 and selects and inputs the prompt into an applicable ML model 180, 190 that is appropriate for the particular prompt. In some embodiments, one or more of the ML models 180, 190 are trained to respond to specific types of inputs. In such instances, the intent management application 170 processes a prompt to identify one or more ML models 180, 190 that have been trained to respond to such a prompt. Upon identifying the one or more appropriate ML models, the intent management application 170 selects one or more appropriate ML model 180, 190 and inputs the prompt into the selected ML model 180, 190.

In general, the ML models 180, 190 can be trained to receive specific inputs, and execute on the received inputs to generate specific outputs. The trained ML models 180, 190 can be trained on a relatively large amount of existing data and optionally any number of results (e.g., evaluations provided by the user) to perform any number and/or types of prediction tasks based on patterns detected in the existing data. In various embodiments, the remote ML models 190 are additional trained ML models that communicate with the server device 160 to receive prompts via the intent management application 170. In some embodiments, the trained ML models 180, 190 are trained using various combinations of data from multiple modalities, such as 2D or 3D design data, command data, textual data, image data, sound data, and so forth. For example, in some embodiments, the one or more trained ML models 180, 190 can include a third-generation Generative Pre-Trained Transformer (GPT-3) model, a specialized version of a GPT-3 model referred to as a “DALL-E2” model, a fourth-generation Generative Pre-Trained Transformer (GPT-4) model, and so forth. In various embodiments, the trained ML models 180, 190 can be trained to generate various ML responses from various combinations of modalities in response to prompts provided by the design application 130. For example, such combinations include text, a CAD object, a geometry, an image, a sketch, a video, an application state, an audio recording, etc.

In some embodiments, one or more ML models 180, 190 are trained to receive geometries of design objects 144 within the overall design and a set of object IDs that specify a set of selected design objects 144 within the overall design, then determine an object label and object details for each selected design object 144, and then output, for each selected design object 144, the associated object ID and corresponding object label and object details. In further embodiments, one or more ML models 180, 190 are trained to receive geometries of design objects 144 within the overall design, a set of object IDs that specify a set of selected design objects 144 within the overall design, and a set of design application commands that were executed on the overall design, then determine a subset of design application commands that were specifically executed on each selected design object 144, and then output, for each selected design object 144, the associated object ID and corresponding subset of design application commands.

The design history 182 includes data and metadata associated with the one or more trained ML models 180 and/or the one or more remote ML models 190 generating ML responses in response to prompts provided by the design application 130. In some embodiments, the design history 182 includes successive iterations of design objects 144 that a single ML model 180 generates in response to a series of prompts. Additionally or alternatively, the design history 182 includes multiple design objects 144 that were generated by different ML models 180, 190 in response to the same prompt. In some embodiments, the design history 182 includes evaluation feedback provided by the user for a given ML response. In such instances, the server device 160 can use the design history 182 as additional training data to retrain the one or more ML models 180.

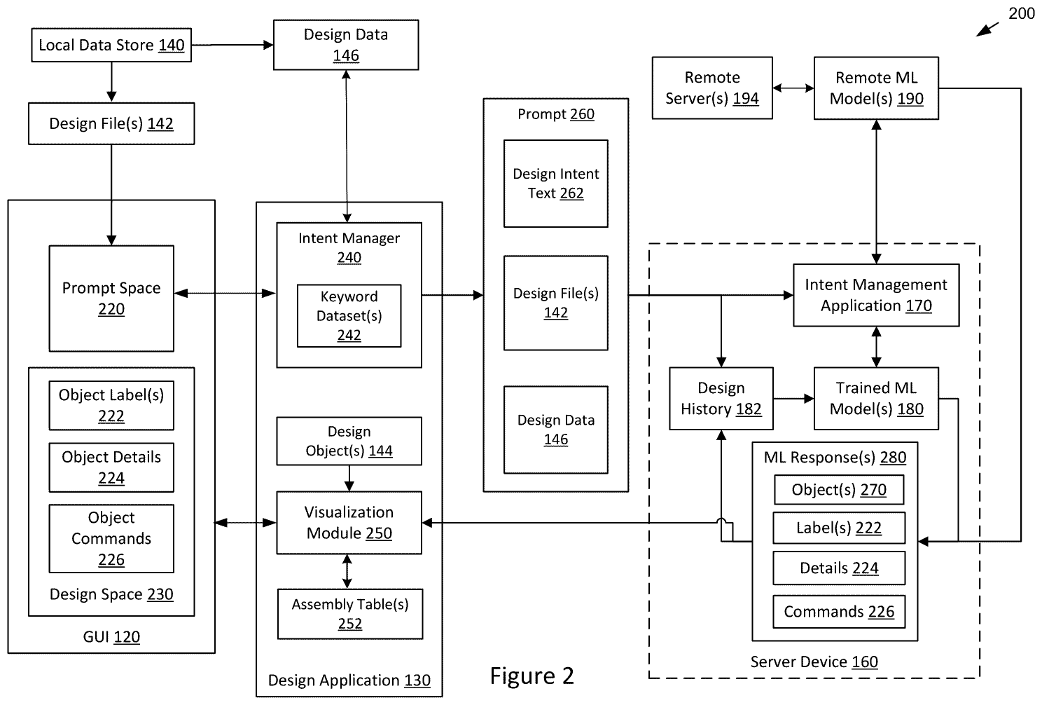

FIG. 2 is a more detailed illustration of the design application 130 of FIG. 1, according to various embodiments. As shown, in some embodiments, the system 200 includes, without limitation, the design application 130, the GUI 120, the local data store 140, the one or more design files 142, the design data 146, the one or more remote servers 194, the server device 160, the remote ML models 190, and a prompt 260.

The GUI 120 includes, without limitation, a prompt space 220 and a design space 230 that can display object labels 222, object details 224, and/or object commands 226. The design application 130 includes, without limitation, an intent manager 240 including one or more keyword datasets 242, the one or more design objects 144, a visualization module 250, and one or more assembly tables 252. The server device 160 includes, without limitation, the intent management application 170, the one or more trained models 180, the design history 182, and one or more ML responses 280 that are generated in response to received prompts 260. An ML response 280 can include design objects 270, object labels 222, object details 224, and/or object commands 226. The prompt 260 includes, without limitation, a design intent text 262, one or more design files 142, and/or design data 146.

As persons skilled in the art will recognize, the techniques described herein are illustrative rather than restrictive and can be altered and applied in other contexts without departing from the broader spirit and scope of the inventive concepts described herein. For example, the techniques described herein can be modified and applied to generate any number of ML responses 280 in a linear fashion, a nonlinear fashion, an iterative fashion, a non-iterative fashion, a recursive fashion, a non-recursive fashion, or any combination thereof during an overall process for generating and evaluating ML responses 280.

In operation, the visualization module 250 of the design application 130 generates and renders the GUI 120, which includes the prompt space 220 and the design space 230. In various embodiments, the design space 230 is a virtual workspace that includes one or more renderings of design objects (e.g., geometries of the current design objects 144 and/or newly generated design objects 270) that form an overall 3D design (such as an assembly). The prompt space 220 is a panel in which a user and/or the design application 130 can input content that is used to generate the prompts 260 to be processed by the one or more ML models 180, 190. A user and/or the design application 130 can provide content for the prompt 260 via the prompt space 220, such as by entering text inputs (queries) into the prompt space 220. The intent manager 240 can determine the intent of text inputs (queries) provided in the prompt space 220 to generate the design intent text 262 that is included in the prompt 260. The prompt 260 can also include non-textual data, such as one or more design files 142 and design data 146 that are stored and retrieved from the local data store 140.

For example, the intent manager 240 can comprise a natural language (NL) processor that parses text input provided in the prompt space 220 by identifying one or more keywords in textual data. In some embodiments, the intent manager 240 includes one or more keyword datasets 242 for identifying the one or more keywords included in textual data. For example, the keyword datasets 242 can include, without limitation, a 3D keyword dataset that includes any number and/or types of 3D keywords, a customized keyword dataset that includes any number and/or types of customized keywords, and/or a user keyword dataset that includes any number and/or types of user keywords (e.g., words and/or phrases specified by a user). The keywords can comprise particular words or phrases (e.g., demonstrative pronouns, technical terms, referential terms, etc.) that are relevant to designing 3D objects. For example, a user and/or the design application 130 can input a regular sentence (“I want a hinge to connect here”) within an input area within the prompt space 220. The intent manager identifies “hinge,” “connect,” and “here” as words relevant to include in the design intent text 262.

After generating the prompt 260, the design application 130 then transmits the prompt 260 to the server device 160. In various embodiments, the intent management application 170 receives the prompt 260 and selects and inputs the prompt 260 into an applicable ML model 180, 190 that is appropriate for the particular prompt. For example, the intent management application 170 can identify a combination of text, design objects, and design data included in the prompt 260 and identify and select a particular ML model 180, 190 that was trained with that combination of modalities. The intent management application 170 then executes the selected ML model by inputting the prompt 260 into the selected ML model. The selected ML model then generates an ML response 280 in response to the prompt 260. An ML response 280 can include one or more design objects 270, object labels 222, object details 224, and/or object commands 226. In some embodiments, the server device 160 includes the generated ML responses 280 in the design history 182. In such instances, the generated ML responses 280 is a portion of the design history 182 that can be used as additional training data to retrain one or more ML models 180.

The visualization module 250 of the design application 130 receives the ML response 280 and displays the contents of the ML response 280 in the prompt space 220 and/or the design space 230 of the GUI 120. In some embodiments, the visualization module 250 displays the design objects 270 and object labels 222 in the design space 230. In some embodiments, the visualization module 250 displays the object details 224 and object commands 226 in the prompt space 220 and/or the design space 230. The visualization module 250 can also store contents of the ML response 280 to an assembly table 252 associated with the current overall design displayed in the design space 230. In these embodiments, a separate assembly table 252 is generated and stored for each overall design (assembly).

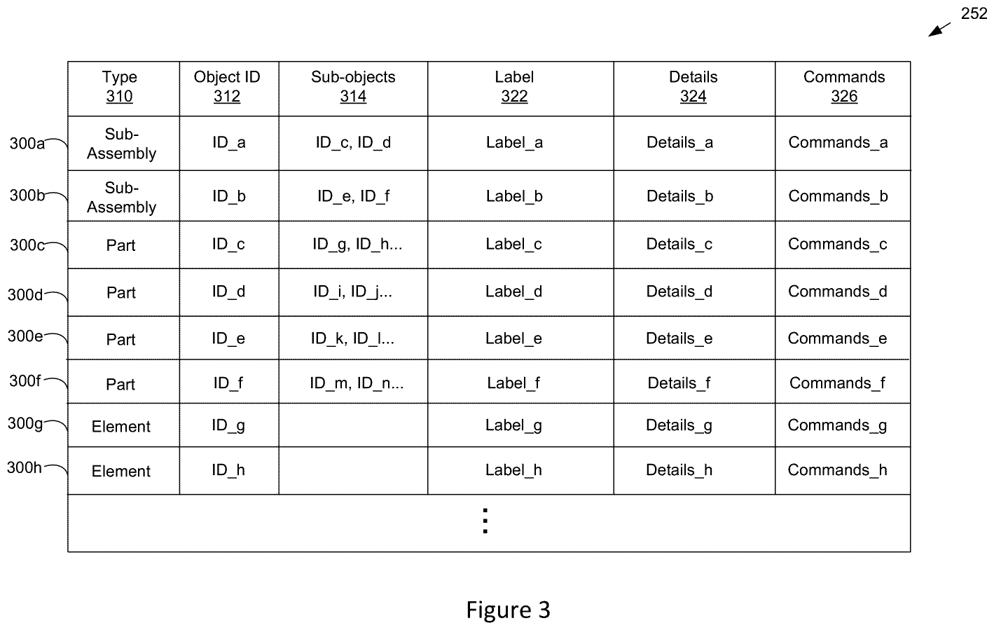

FIG. 3 is a conceptual diagram of one of the assembly tables 252 of FIG. 2, according to various embodiments. In some embodiments, the assembly table 252 comprises any type of data structure or data container for storing and organizing data. The design application 130 can generate and store a separate assembly table 252 to memory 116 for each overall design (assembly). Each assembly table 252 stores a variety of object information for design objects 144 of the overall design.

As shown, the assembly table 252 includes a plurality of entries 300 (such as 300a, 300b, etc.), each entry 300 representing a particular design object 144 of the overall design. Each entry 300 comprises a plurality of data fields, including a type field 310, an object ID field 312, a sub-objects field 314, a label field 322, a details field 324, and a commands field 326. The type field 310 specifies a type of the corresponding design object 144, such as a sub-assembly object, part object, or element object. The object ID field 312 specifies the object ID assigned to the corresponding design object 144. The sub-objects field 314 specifies object IDs for any design objects 144 contained in the corresponding design object 144. For example, if the corresponding design object 144 is a sub-assembly object, the sub-objects field 314 specifies object IDs for one or more part objects contained in the sub-assembly object. For example, if the corresponding design object 144 is a part object, the sub-objects field 314 specifies object IDs for one or more element objects contained in the part object. The label field 322 contains the object label 222 received for the corresponding design object 144. The details field 324 contains the object details 224 received for the corresponding design object 144. The commands field 326 contains the object commands 226 received for the corresponding design object 144.

### OVERVIEW OF EMBODIMENTS

In some embodiments, the design application 130 implements an object information feature/function that automatically provides various content for the prompt 260 via the prompt space 220 (by automatically entering content inputs into the prompt space 220) or by directly generating the prompt 260 with the various content. In these embodiments, the design application 130 automatically generates one or more prompts 260 in response to the user triggering/initiating an object labelling function (e.g., via a first predetermined hotkey input), and the transmits the one or more prompts 260 to the server device 160. Each prompt 260 can include design intent text 262, one or more design files 142, and/or design data 146. The design intent text 262 can include one or more text requests/queries for objection information for selected design objects 144, the one or more design files 142 can include geometries for one or more design objects 144, and the design data 146 can include object IDs for the selected design objects 144 and/or design application commands that were executed on the overall design. The server device 160 then implements one or more ML models 180, 190 to generate and return one or more ML responses 280 based on the one or more prompts 260.

In general, the one or more prompts 260 requests/queries for various object information (labels, details, and commands) associated with one or more selected design objects 144 of the overall design displayed in the design space 230. The object information returned in the one or more ML responses 280 can comprise object labels 222, object details 224, and/or object commands 226 for one or more selected design objects 144 of the overall design. The overall design (assembly) can include one or more sub-assembly objects, each sub-assembly object comprising one or more part objects, and each part object comprising one or more element objects (geometric primitives). The object labels 222 can identify the specific types of physical or virtual components the design objects are representing. The types of object labels 222 and object details 224 returned in the one or more ML responses 280 can depend on the type of the selected design objects 144, whereby the types of object labels 222 and object details 224 can vary for assembly objects, part objects, and element objects.

In some embodiments, the one or more selected design objects 144 for which such object information is requested are selected from the overall design based on which design objects 144 are currently displayed in the design space 230 and on a current zoom level implemented in the design space 230. In particular, if the current zoom level is within a first zoom-level range corresponding to sub-assembly objects, then the selected design objects 144 for which object information is requested comprise only sub-assembly objects within the overall design, such as all sub-assembly objects currently displayed in the design space 230. If the current zoom level is within a second zoom-level range corresponding to part objects, then the selected design objects 144 for which object information is requested comprise only part objects within the overall design, such as all part objects currently displayed in the design space 230. If the current zoom level is within a third zoom-level range corresponding to element objects, then the selected design objects 144 for which object information is requested comprise only element objects within the overall design, such as all element objects currently displayed in the design space 230.

In some embodiments, in response to the user initiating the object labelling function, the design application 130 generates a first prompt 260 comprising design intent text 262, one or more design files 142, and design data 146. If the current zoom level corresponds to sub-assembly objects, for the first prompt 260 the one or more design files 142 include geometries for all design objects 144 (and associated metadata including object IDs) of the overall design. The design data 146 includes a set of object IDs specifying object IDs for only the sub-assembly objects within the overall design, such as only those sub-assembly objects currently displayed in the design space 230. The design data 146 also includes a set of design application commands that were previously executed on the overall design to generate and/or modify the various design objects 144 of the overall design. The design intent text 262 comprises a text query requesting object labels 222, object details 224, and/or object commands 226 associated with each sub-assembly object specified in the set of object IDs of the design data 146.

Similarly, if the current zoom level corresponds to part objects, for the first prompt 260 the one or more design files 142 include geometries for all design objects 144 (and associated metadata including object IDs) of the overall design. The design data 146 includes a set of object IDs specifying object IDs for only the part objects within the overall design, such as only those part objects currently displayed in the design space 230. The design data 146 also includes all design application commands that were previously executed on the overall design to generate and/or modify various design objects 144 of the overall design. The design intent text 262 comprises a text query requesting object labels 222, object details 224, and/or object commands 226 associated with each part object specified in the set of object IDs of the design data 146.

If the current zoom level corresponds to element objects, for the first prompt 260 the one or more design files 142 include only geometries for element objects 144 (and associated metadata including object IDs) that are currently displayed in the design space 230. The design data 146 includes a set of object IDs specifying object IDs for only the element objects within the overall design, such as only those element objects currently displayed in the design space 230. The design data 146 also includes all design application commands that were previously executed on the overall design to generate and/or modify various design objects 144 of the overall design. The design intent text 262 comprises a text query requesting object labels 222, object details 224, and/or object commands 226 associated with each element object specified in the set of object IDs of the design data 146.

In some embodiments, the first prompt 260 can be divided into a plurality of different prompts 260, such as a prompt containing the one or more design files 142 and the design data 146, another prompt containing the text query requesting the object labels 222, another prompt containing the text query requesting the object details 224, and another prompt containing the text query requesting the object commands 226. In other embodiments, the first prompt 260 can be divided into a plurality of different prompts 260 in a different manner.

Note that in the first prompt 260 for both sub-assembly objects and part objects, the design files 142 include all design objects 144 of the overall design, which provides valuable context and background information for the ML models 180, 190 to more accurately determine the object labels 222 and object details 224 for the sub-assembly objects and part objects. In particular, providing all design objects 144 of the overall design provides context for a particular design object 144 in relation to the overall design and provides context within the overall design. However, in the first prompt for element objects, the design files 142 do not need to include all design objects 144 of the overall design to provide context and background information, as only geometries associated with the selected element objects should suffice for the ML models 180, 190 to accurately determine the object labels 222 and object details 224 for the element objects.

To generate the set of object IDs in the design data 146 for the selected sub-assembly objects, the design application 130 can parse the metadata associated with the design objects 144 currently displayed in the design space 230 to identify design objects 144 that are sub-assembly objects and determine the object ID assigned to each sub-assembly object. For each selected sub-assembly object, the design application 130 can also generate an entry 300 in the assembly table 252 representing the sub-assembly object and store the object ID to the generated entry 300. Likewise, to generate the set of object IDs in the design data 146 for the selected part objects, the design application 130 can parse the metadata associated with the design objects 144 currently displayed in the design space 230 to identify design objects 144 that are part objects and determine the object ID assigned to each part object. For each selected part object, the design application 130 can also generate an entry 300 in the assembly table 252 representing the part object and store the object ID to the generated entry 300. Likewise, to generate the set of object IDs in the design data 146 for the selected element objects, the design application 130 can parse the metadata associated with the design objects 144 currently displayed in the design space 230 to identify design objects 144 that are element objects and determine the object ID assigned to each element object. For each selected element object, the design application 130 can also generate an entry 300 in the assembly table 252 representing the element object and store the object ID to the generated entry 300.

The design data 146 can also include all design application commands that were previously executed on the overall design to generate and/or modify the various design objects 144 of the overall design. In general, as the user invokes various design application commands (such as extrude, loft, planar, blend, patch, extend, revolve, network, sweep, filet, offset, etc.), the design application 130 executes the invoked commands and stores a record of the executed commands, for example, to the local memory 116. The design application 130 can retrieve the record of all the executed commands from memory 116 and add the commands to the design data 146. Typically, the design application 130 simply stores a stream of all design application commands that were executed on the overall design in general, but does not specify which design application commands were executed on particular design objects 144 within the overall design. Therefore, the user cannot easily determine which design application commands were previously executed on which particular design objects 144 within the overall design. Advantageously, the design application 130 can request that the one or more ML models 180, 190 to identify, for each selected design object 144, a subset of the design application commands specified in the design data 146 that were specifically executed on the selected design object 144, for example, to generate and/or modify the selected design object 144. In this manner, the user can easily view and understand the design application commands that were used to generate and/or modify the selected design object 144.

In some embodiments, the design intent text 262 specifies that an object label 222 for a selected design object 144 comprises an identification of a specific type of component that the design object 144 represents. For example, the object labels 222 can identify the specific types of physical or virtual components the design objects are representing. For example, an object label 222 for a selected design object 144 can comprise an identification of a specific type of sub-assembly, part, or element that the design object 144 represents. The design intent text 262 can also specify that object details 224 for a selected design object 144 comprises detailed information that further describes the specific type of sub-assembly, part, or element that the design object 144 represents. The design intent text 262 can also specify that object details 224 for a selected design object 144 further comprises alternative geometries for the specific type of sub-assembly or part that the design object 144 represents, such as alternative design objects 270. The design intent text 262 can further specify that object commands 226 for a selected design object 144 comprises a subset of design application commands that were specifically executed on the selected design object 144, for example, to generate and/or modify the selected design object 144. The subset of design application commands associated with the selected design object 144 are identified from the set of design application commands included in the design data 146.

After generating the first prompt 260, the design application 130 transmits the first prompt 260 to the server device 160. The server device 160 implements one or more ML models 180, 190 to generate and return one or more ML responses 280 based on the first prompt 260. The server device 160 can first implement one or more ML models 180, 190 trained to identify various types of sub-assemblies, parts, or elements represented by various 3D design objects to generate an object label 222 that identifies each design object 144 selected/specified in first prompt 260 (as specified via the object ID for the design object 144 being included in the design data 146). The server device 160 can then generate and transmit a first ML response 280 for the first prompt 260 to the design application 130. The first ML response 280 can include, for each design object 144 specified in the first prompt 260, the corresponding object ID and object label 222 for the design object 144. The design application 130 receives the first ML response 280 and displays the object labels 222 in the design space 230 by displaying each object label 222 adjacent to the corresponding design object 144 within the overall design. In other embodiments, an object label 222 is not placed adjacent to the corresponding design object 144, but includes an indicator (such as an arrow) that points to the corresponding design object 144. The design application 130 also stores the object label 222 received for each specified design object 144 in an entry 300 representing the design object 144 in the assembly table 252.

Concurrently, as the server device 160 generates and transmits the first ML response 280, the server device 160 can simultaneously implement one or more ML models 180, 190 that are trained to determine detailed descriptive information and/or alternative geometries for various types of sub-assemblies, parts, or elements to generate object details 224 for each design object 144 specified in first prompt 260. The server device 160 can then generate and transmit a second ML response 280 for the first prompt 260 to the design application 130. The second ML response 280 can include, for each design object 144 specified in the first prompt 260, the corresponding object ID and object details 224 for the design object 144. The design application 130 receives the second ML response 280 but does not display the object details 224 in the GUI 120 until the user later requests the object details 224 for a particular design object 144. The design application 130 also stores the object details 224 received for each specified design object 144 in an entry 300 representing the design object 144 in the assembly table 252.

Concurrently, as the server device 160 generates and transmits the first ML response 280 and generates and transmits the second ML response 280, the server device 160 can simultaneously implement one or more ML models 180, 190 that are trained to identify design application commands that are executed on various design objects 144 to determine one or more object commands 226 associated with each design object 144 specified in first prompt 260. The server device 160 can then generate and transmit a third ML response 280 for the first prompt 260 to the design application 130. The third ML response 280 can include, for each design object 144 specified in the first prompt 260, the corresponding object ID and object commands 226 for the design object 144. The object commands 226 for a design object 144 specifies a subset of the design application commands specified in the design data 146, the subset of the design application commands being previously executed on the design object 144. The design application 130 receives the third ML response 280 but does not display the object commands 226 in the GUI 120 until the user later requests the object commands 226 associated with a particular design object 144. The design application 130 also stores the object commands 226 received for each specified design object 144 in an entry 300 representing the design object 144 in the assembly table 252.

If the first prompt relates to sub-assembly objects, the object label 222 returned for a sub-assembly object can comprise an identification of the specific type of physical sub-assembly represented by the sub-assembly object, such as a frame sub-assembly, a controls sub-assembly, a drivetrain sub-assembly, etc. If the first prompt relates to part objects, the object label 222 returned for a part objects can comprise an identification of the specific type of physical part represented by the part object, such as a pedal, chainring, chain, etc. If the first prompt relates to element objects, the object label 222 returned for an element object can comprise an identification of the specific type of virtual element represented by the element object, such as a vertex, an edge, a face, a boundary, or a solid.

If the first prompt relates to sub-assembly objects or part objects, the object details 224 returned for a sub-assembly or part object can include additional descriptive information of the sub-assembly or part object, such as manufacturing information associated with the sub-assembly or part object. For example, the object details 224 returned for a sub-assembly or part object can include typical physical dimensions (width, height, depth), typical geometric shapes, typical weights or mass, typical materials, typical manufacturing processes used, typical colors, environmental information (such as embodied carbon or embodied greenhouse gas emissions released during the life cycle), and the like. If the first prompt relates to element objects, the object details 224 returned for an element object can include a technical definition of the element object, such as a technical definition for a vertex, an edge, a face, a boundary, or a solid. For example, the one or more ML models 180, 190 can perform an Internet search for such descriptive information for a sub-assembly, part, or element object based on the object label 222 determined for the sub-assembly, part, or element object, and retrieve the descriptive information from one or more remote servers 194. As another example, such descriptive information can be embedded in the trained ML model 180, 190 itself. In some embodiments, the object details 224 returned for a sub-assembly or part object can also include alternative geometries, such as alternative design objects 270, for a sub-assembly or part object.

In some embodiments, the one or more ML models 180, 190 trained to generate the object labels 222 for the design objects 144 can comprise image to text ML models, 3D geometry/object to text ML models, ML models that are trained on a particular type of object data based on contents in the design, and the like. In some embodiments, the one or more ML models 180, 190 trained to generate the object details 224 for the design objects 144 can comprise Large Language ML Models and the like. In addition, a generative ML model can be trained to generate alternative design objects 270 comprising alternative 3D geometry for sub-assembly or part objects in response to a received text description (such as the object label 222 determined for the sub-assembly or part object). In some embodiments, the one or more ML models 180, 190 trained to determine object commands 226 associated with design objects 144 can comprise Large Language ML Models and the like.

As discussed above, when the design application 130 receives the first ML response 280 comprising the object labels 222, the design application 130 displays each object label 222 adjacent to the corresponding design object 144 within the overall design. The design application 130 receives the second ML response 280 comprising the object details 224, but does not display the object details 224 in the GUI 120 until the user later requests the object details 224 for a particular design object 144. Likewise, the design application 130 receives the third ML response 280 comprising the object commands 226, but does not display the object commands 226 in the GUI 120 until the user later requests the object commands 226 for a particular design object 144. The design application 130 also stores the object label 222, object details 224, and object commands 226 received for each specified design object 144 in an entry 300 representing the design object 144 in the assembly table 252.

The design application 130 provides various tools to enable the user to navigate and interact with the overall design in the design space 230, such as to select and interact with various design objects 144 within the overall design. The user can select a particular design object 144 within the overall design and trigger/initiate an object detail function (e.g., via a second predetermined hotkey input). For example, the user can select the particular design object 144 by hovering the cursor over or clicking on the particular design object 144 or the corresponding object label 222. In response, the design application 130 can retrieve the object details 224 for the selected design object 144 from the assembly table 252, and display the object details 224 in the design space 230 adjacent to the selected design object 144. In other embodiments, object details 224 is not placed adjacent to the corresponding design object 144, but includes an indicator (such as an arrow) that points to the corresponding design object 144. In other embodiments, the object details 224 can be displayed in the prompt space 220. When the user moves the cursor away from the selected design object 144 and/or corresponding object label 222, the design application 130 no longer displays the object details 224 in the GUI 120.

The user can also select a particular design object 144 within the overall design and trigger/initiate an object command function (e.g., via a third predetermined hotkey input). For example, the user can select the particular design object 144 by hovering the cursor over or clicking on the particular design object 144 or the corresponding object label 222. In response, the design application 130 can retrieve the object commands 226 for the selected design object 144 from the assembly table 252, and display the object commands 226 in the design space 230 adjacent to the selected design object 144. In other embodiments, object commands 226 is not placed adjacent to the corresponding design object 144, but includes an indicator (such as an arrow) that points to the corresponding design object 144. In other embodiments, the object commands 226 can be displayed in the prompt space 220. When the user moves the cursor away from the selected design object 144 and/or corresponding object label 222, the design application 130 no longer displays the object commands 226 in the GUI 120.

As the user continues to navigate and interact with the overall design in the design space 230, the labels 222 displayed in the design space 230 and the information in the assembly table 252 can be continually updated. For example, if the user is currently at a zoom level corresponding to sub-assembly objects and labels 222 for sub-assembly objects are currently displayed in the design space 230, the user can change to a zoom level corresponding to part objects and trigger/initiate the object labelling function, which causes the design application 130 to generate a second prompt 260 for requesting object information for selected part objects. When the ML responses 280 containing the object labels 222, object details 224, and object commands 226 for the selected part objects are received, the design application 130 can display the object labels 222 for the selected part objects in the design space 230, and update the assembly table 252 with the object labels 222, object details 224, and object commands 226 for the selected part objects.

In addition, the user may submit a feedback prompt providing an evaluation indicating whether the received object labels 222, object details 224, and/or object commands 226 for a particular design object 144 are correct. For example, the follow-up prompt can specify that a particular object label 222 for a particular design object 144 is incorrect, particular object details 224 for a particular design object 144 is incorrect, and/or particular object commands 226 associated with a particular design object 144 are incorrect. The server device 160 can then store to the design history 182 the particular design object 144 and the feedback prompt(s) for the particular design object 144 as additional training data for retraining the one or more ML models 180, 190 for improving the accuracy of the one or more ML models 180, 190 in identifying object labels 222, object details 224, and/or object commands 226 for design objects 144.

Advantageously, the design application 130 automatically generates and transmits the first prompt 260 in response to the user triggering/initiating the object labelling function (e.g., via a first predetermined hotkey input). In response to the first prompt 260, the server device 160 returns the object labels 222, object details 224, and/or object commands 226 for selected design objects 144. Therefore, in response to receiving a single predetermined hotkey input (the first predetermined hotkey input), the design application 130 requests and receives a wide variety of object information from the server device 160 for selected design objects 144. Advantageously, the selected design objects 144 are selected from the overall design based on the current zoom level, which indicates the current granularity level of focus of the user. As such, the selected design objects 144 likely reflect the type of design objects 144 (sub-assembly, part, or element objects) that are the current focus of the user.

Advantageously, the object labels 222 for the selected design objects 144 are received and displayed in the GUI 120 quickly/immediately, while concurrently the object details 224 and object commands 226 for the selected design objects 144 are being generated and transmitted by the server device 160 and stored to the assembly table 252. In this manner, while the user reviews the object labels 222 displayed in the GUI 120 for the selected design objects 144, the object details 224 and object commands 226 for the selected design objects 144 are also being concurrently generated and stored (preloaded) to the assembly table 252 in the background so that the object details 224 and object commands 226 can be ready for display immediately upon being selected for a particular design object 144 by the user, thus improving the user experience.

### Automated Object Information Function for Design Objects

Initially, the design application 130 generates the GUI 120 comprising the design space 230 comprising design objects 144. A design object 144 can comprise an assembly, a part, or an element. An assembly comprises a design object 144 that includes a plurality of connected but distinct parts, each part comprising a separate design object 144. A part comprises a design object 144 that includes a plurality of connected but distinct elements (such as edges, faces, etc.), each element comprising a separate design object 144. Therefore, an assembly object includes a plurality of sub-objects comprising part objects, and a part object includes a plurality of sub-objects comprising element objects. The design application 130 provides various tools to select, manipulate, and modify an assembly object, a part object, or an element object. For example, the design application 130 can provide an assembly selection tool, a part selection tool, and an element selection tool.

As another example, the design application 130 can provide zoom tools for viewing the design space 230 that enable zooming out to view the overall assembly and select a particular sub-assembly, zooming into a view of a sub-assembly to view and select a particular part of the sub-assembly, and further zooming into a view of a part to view and select a particular element of the part. In general, different zoom-level ranges can correspond to different object types. For example, a first zoom-level range can correspond to sub-assembly objects where the user is zooming out to focus on sub-assembly objects. A second zoom-level range can correspond to part objects where the user is zooming in to focus on part objects. A third zoom-level range can correspond to element objects where the user is zooming yet further in to focus on element objects in general. In relative terms, the first zoom-level range comprises the lowest amount of zoom, the second zoom-level range comprises the second highest amount of zoom, and the third zoom-level range comprises the highest amount of zoom.

In some embodiments, the selected design objects 144 for which object labels 222 is requested are selected from the overall design based on a current zoom level implemented in the design space 230. In particular, if the current zoom level is within a first zoom-level range corresponding to sub-assembly objects, then the selected design objects 144 for which object information is requested comprise only sub-assembly objects within the overall design, such as all sub-assembly objects currently displayed in the design space 230. If the current zoom level is within a second zoom-level range corresponding to part objects, then the selected design objects 144 for which object information is requested comprise only part objects within the overall design, such as all part objects currently displayed in the design space 230. If the current zoom level is within a third zoom-level range corresponding to element objects, then the selected design objects 144 for which object information is requested comprise only element objects within the overall design, such as all element objects currently displayed in the design space 230. Advantageously, this reduces visual clutter that can be caused from displaying labels for all design objects 144 within the overall design at the same time. Instead, the present techniques will display labels for only those design objects 144 within the overall design that the user is currently focusing on based on the current zoom level.

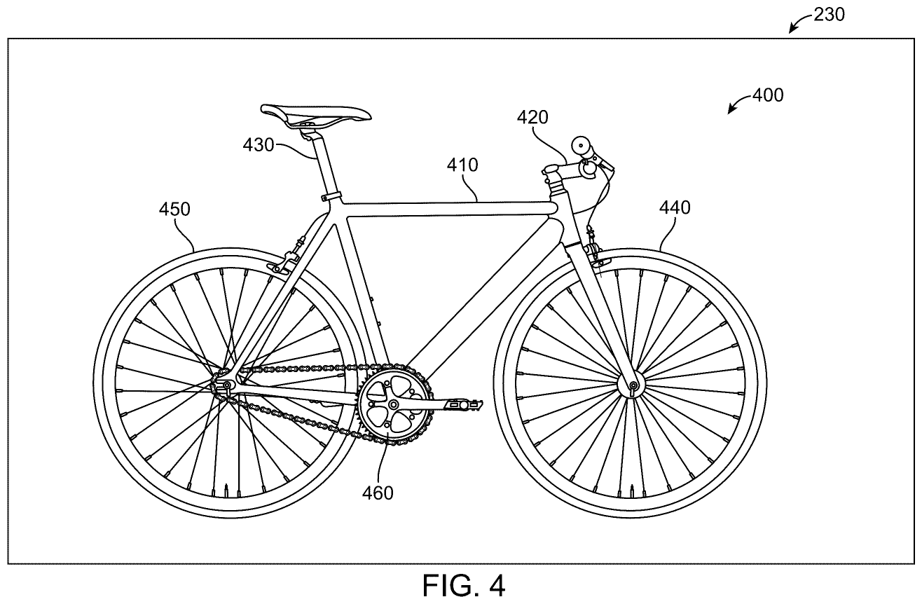

In this regard, FIGS. 4-7 illustrate an automated object-information feature/function for sub-assembly objects. FIG. 4 is an exemplar illustration of a bike assembly 400 shown at a first zoom level within the design space 230 of FIG. 2, according to various embodiments. As shown, the design space 230 displays the bike assembly 400 (overall design) comprising a plurality of sub-assembly objects 144, including a frame sub-assembly 410, a controls sub-assembly 420, a seat sub-assembly 430, a front wheel sub-assembly 440, a rear wheel sub-assembly 450, and a drivetrain sub-assembly 460. In other embodiments, the bike assembly 400 includes additional sub-assemblies. However, for illustration clarity, not all possible sub-assemblies of a bicycle are shown.

The user initiates the object labelling function (e.g., via the first predetermined hotkey input), and in response, the design application 130 determines that the current zoom level comprises a first zoom level that is within the first zoom-level range corresponding to sub-assembly objects. The design application 130 then generates a first prompt 260 comprising design intent text 262, design files 142, and design data 146. The design files 142 include geometries for all design objects 144 of the bike assembly 400. The design data 146 includes a set of object IDs for only the sub-assembly objects 410-460 (and not part objects or element objects) within the bike assembly 400, such as only those sub-assembly objects 410-460 currently displayed in the design space 230. The design data 146 also includes a set of design application commands that were previously executed on the bike assembly 400. The design intent text 262 comprises a text query requesting object labels 222, object details 224, and/or object commands 226 associated with each sub-assembly object 410-460 specified in the set of object IDs of the design data 146.

The design application 130 transmits the first prompt 260 to the server device 160, which implements one or more ML models 180, 190 to generate and return one or more ML responses 280 based on the first prompt 260. The server device 160 can then generate and transmit a first ML response 280 that includes, for each sub-assembly object 410-460 specified in the first prompt 260, the corresponding object ID and object label 222 for the sub-assembly object 410-460. The design application 130 receives the first ML response 280 and displays the object labels 222 in the design space 230 by displaying each object label 222 adjacent to the corresponding sub-assembly object 410-460. The design application 130 also stores the object label 222 received for each sub-assembly object 410-460 in the assembly table 252.

As a general matter, a first GUI item can be placed “proximate” or “adjacent” to a second GUI item within the design space 230 using various techniques. For example, the center point of the first GUI item can be placed within a predetermined distance from the center point of the second GUI item within the design space 230. For example, the predetermined distance can be measured in terms of pixels or the native coordinate system of the design space 230. In other embodiments, other techniques are used to place a first GUI item “proximate” or “adjacent” to a second GUI item within the design space 230.

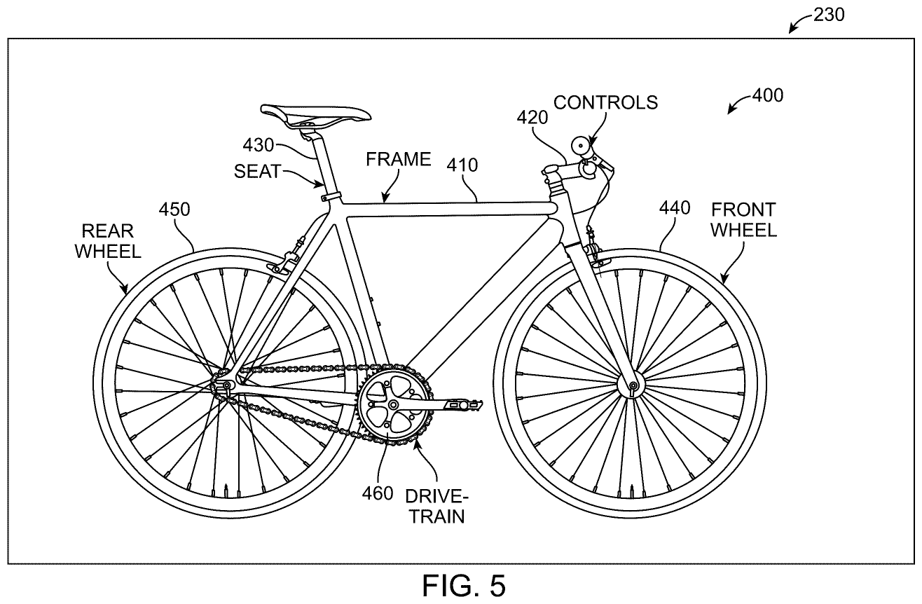

FIG. 5 is an exemplar illustration of the bike assembly 400 of FIG. 4 with sub-assembly object labels, according to various embodiments. As shown, the design space 230 displays the bike assembly 400 with object labels adjacent to the corresponding sub-assembly objects 410-460. As shown, the object label “FRAME” is displayed adjacent to the frame sub-assembly 410, the object label “CONTROLS” is displayed adjacent to the controls sub-assembly 420, the object label “SEAT” is displayed adjacent to the seat sub-assembly 430, the object label “FRONT WHEEL” is displayed adjacent to the front wheel sub-assembly 440, the object label “REAR WHEEL” is displayed adjacent to the rear wheel sub-assembly 450, the object label “DRIVETRAIN” is displayed adjacent to the drivetrain sub-assembly 460. In other embodiments, an object label 222 is not placed adjacent to the corresponding design object 144, but includes an indicator (such as an arrow) that points to the corresponding design object 144.

Concurrently, as the server device 160 generates and transmits the first ML response 280, the server device 160 can simultaneously implement one or more ML models 180, 190 to generate and transmit a second ML response 280 that includes, for each sub-assembly object 410-460 specified in the first prompt 260, the corresponding object ID and object details 224 for the sub-assembly object. The design application 130 receives the second ML response 280 but does not yet display the object details 224 in the GUI 120. The design application 130 also stores the object details 224 received for each sub-assembly object 410-460 in the assembly table 252. The user then selects, for example, the rear wheel sub-assembly 450 and initiates the object detail function (e.g., via a second predetermined hotkey input). In response, the design application 130 retrieves the object details 224 for the selected rear wheel sub-assembly 450 from the assembly table 252, and displays the object details 224 in the design space 230 adjacent to the selected rear wheel sub-assembly 450.

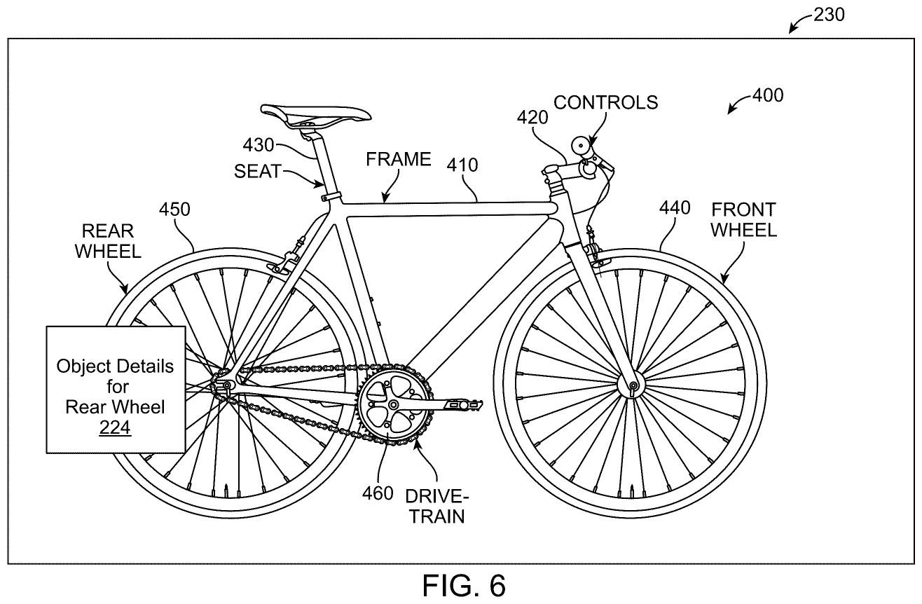

FIG. 6 is an exemplar illustration of the bike assembly 400 of FIG. 4 with sub-assembly details, according to various embodiments. As shown, the design space 230 displays the bike assembly 400 with object details 224 for the rear wheel sub-assembly 450 adjacent to the rear wheel sub-assembly 450. In other embodiments, object details 224 is not placed adjacent to the corresponding design object 144, but includes an indicator (such as an arrow) that points to the corresponding design object 144. In other embodiments, the object details 224 can be displayed in the prompt space 220. When the user moves the cursor away from the selected rear wheel sub-assembly 450, the design application 130 no longer displays the object details 224 in the GUI 120.

Concurrently, as the server device 160 generates and transmits the first ML response 280 and the second ML response 280, the server device 160 can simultaneously implement one or more ML models 180, 190 to determine one or more object commands 226 associated with each sub-assembly object 410-460 specified in first prompt 260. The server device 160 can then generate and transmit a third ML response 280 that includes, for each sub-assembly object 410-460 specified in the first prompt 260, the corresponding object ID and object commands 226 for the sub-assembly object. The design application 130 receives the third ML response 280 but does not yet display the object commands 226 in the GUI 120. The design application 130 also stores the object commands 226 received for each specified sub-assembly object 410-460 in the assembly table 252. The user then selects the rear wheel sub-assembly 450 and initiates the object command function (e.g., via a third predetermined hotkey input). In response, the design application 130 retrieves the object commands 226 for the selected rear wheel sub-assembly 450 from the assembly table 252, and displays the object commands 226 in the design space 230 adjacent to the selected rear wheel sub-assembly 450.

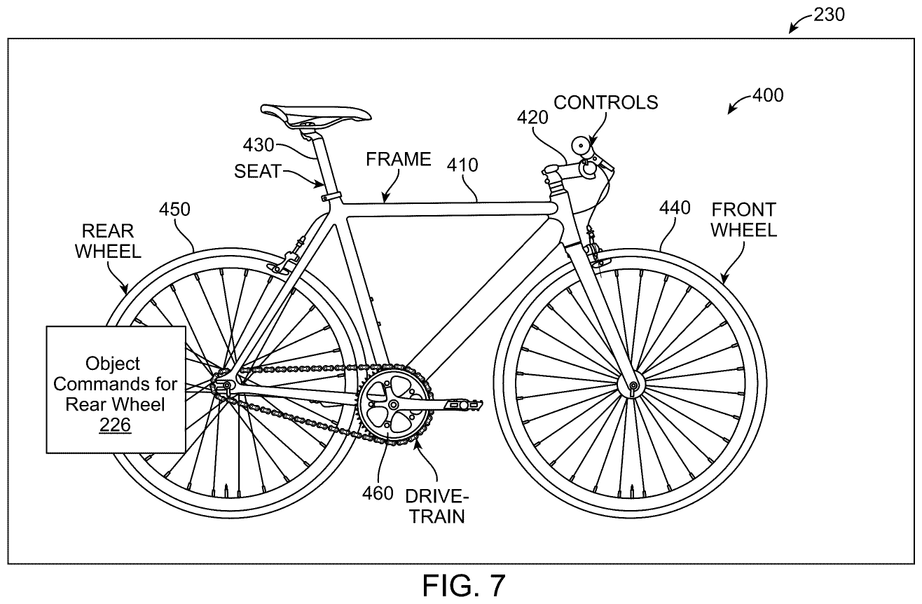

FIG. 7 is an exemplar illustration of the bike assembly 400 of FIG. 4 with sub-assembly commands, according to various embodiments. As shown, the design space 230 displays the bike assembly 400 with object commands 226 for the rear wheel sub-assembly 450 adjacent to the rear wheel sub-assembly 450. In other embodiments, object commands 226 is not placed adjacent to the corresponding design object 144, but includes an indicator (such as an arrow) that points to the corresponding design object 144. In other embodiments, the object commands 226 can be displayed in the prompt space 220. When the user moves the cursor away from the selected rear wheel sub-assembly 450, the design application 130 no longer displays the object commands 226 in the GUI 120.

As the user continues to navigate and change zoom levels within the design space 230, the current zoom level can exit the first zoom-level range corresponding to sub-assembly objects and enter the second or third zoom-level ranges. In some embodiments, when the current zoom level is no longer within the first zoom-level range, the design application 130 no longer displays the object labels 222 for the sub-assembly objects within the design space 230. For example, the current zoom level can enter the second zoom-level range corresponding to part objects.

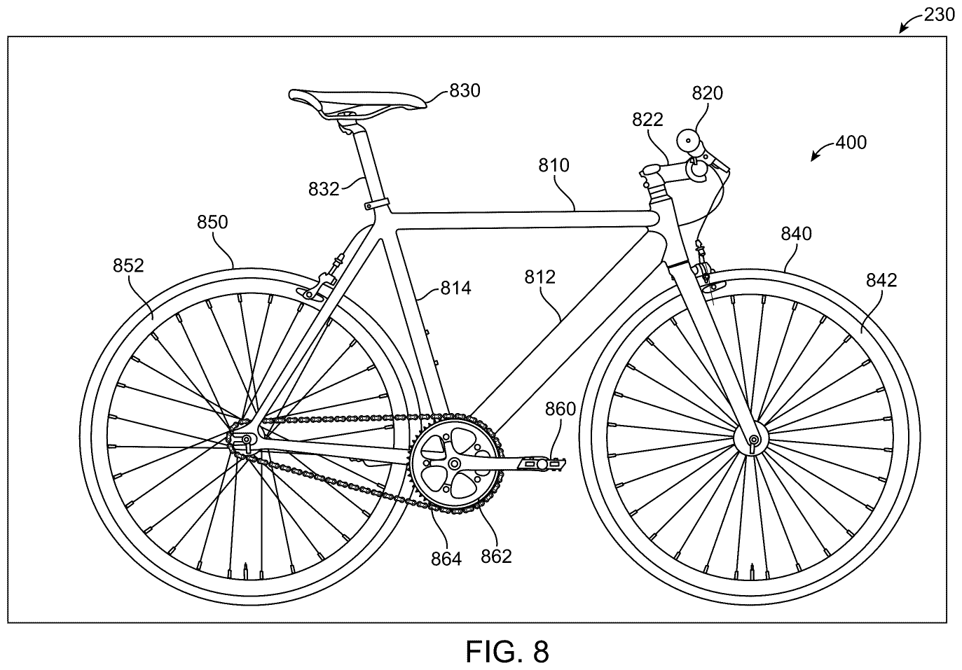

In this regard, FIGS. 8-12 illustrate an automated object-information feature/function for part objects. FIG. 8 is an exemplar illustration of the bike assembly 400 shown at a second zoom level within the design space 230 of FIG. 2, according to various embodiments. As shown, the design space 230 displays the bike assembly 400 (overall design) comprising a plurality of part objects 144, including a top tube part 810, a down tube part 812, a seat tube part 814, a handles part 820, a stem part 822, a saddle part 830, a seat post part 832, a front tire part 840, a front rim part 842, a rear tire part 850, a rear rim part 852, a pedals part 860, a chain ring part 862, and a chain part 864. In other embodiments, the bike assembly 400 includes additional parts. However, for illustration clarity, not all possible parts of a bicycle are shown.

The user initiates the object labelling function (e.g., via the first predetermined hotkey input), and in response, the design application 130 determines that the current zoom level comprises a second zoom level that is within the second zoom-level range corresponding to part objects. The design application 130 then generates a second prompt 260 comprising design intent text 262, design files 142, and design data 146. The design files 142 include geometries for all design objects 144 of the bike assembly 400. The design data 146 includes a set of object IDs for only the part objects 810-864 (and not sub-assembly objects or element objects) within the bike assembly 400, such as only those part objects 810-864 currently displayed in the design space 230. The design data 146 also includes a set of design application commands that were previously executed on the bike assembly 400. The design intent text 262 comprises a text query requesting object labels 222, object details 224, and/or object commands 226 associated with each part object 810-864 specified in the set of object IDs of the design data 146.

The design application 130 transmits the second prompt 260 to the server device 160, which implements one or more ML models 180, 190 to generate and return one or more ML responses 280 based on the second prompt 260. The server device 160 can then generate and transmit a first ML response 280 that includes, for each part object 810-864 specified in the second prompt 260, the corresponding object ID and object label 222 for the part object 810-864. The design application 130 receives the first ML response 280 and displays the object labels 222 in the design space 230 by displaying each object label 222 adjacent to the corresponding part object 810-864. The design application 130 also stores the object label 222 received for each part object 810-864 in the assembly table 252.

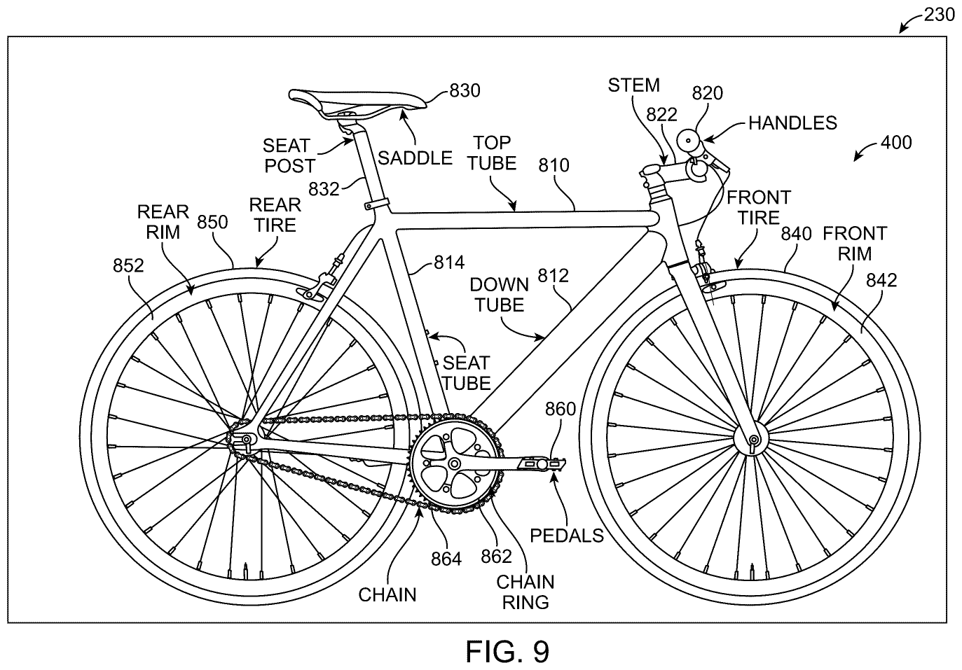

FIG. 9 is an exemplar illustration of the bike assembly 400 of FIG. 8 with part object labels, according to various embodiments. As shown, the design space 230 displays the bike assembly 400 with object labels adjacent to the corresponding part objects 810-864. As shown, the object label “TOP TUBE” is displayed adjacent to the top tube part 810, the object label “DOWN TUBE” is displayed adjacent to the down tube part 812, the object label “SEAT TUBE” is displayed adjacent to the seat tube part 814, the object label “HANDLES” is displayed adjacent to the handles part 820, the object label “STEM” is displayed adjacent to the stem part 822, the object label “SADDLE” is displayed adjacent to the saddle part 830, the object label “SEAT POST” is displayed adjacent to the seat post part 832, the object label “FRONT TIRE” is displayed adjacent to the front tire part 840, the object label “FRONT RIM” is displayed adjacent to the front rim part 842, the object label “REAR TIRE” is displayed adjacent to the rear tire part 850, the object label “REAR RIM” is displayed adjacent to the rear rim part 852, the object label “PEDALS” is displayed adjacent to the pedals part 860, the object label “CHAIN RING” is displayed adjacent to the chain ring part 862, and the object label “CHAIN” is displayed adjacent to the chain part 864. In other embodiments, an object label 222 is not placed adjacent to the corresponding design object 144, but includes an indicator (such as an arrow) that points to the corresponding design object 144.

Concurrently, as the server device 160 generates and transmits the first ML response 280, the server device 160 can simultaneously implement one or more ML models 180, 190 to generate and transmit a second ML response 280 that includes, for each part object 810-864 specified in the second prompt 260, the corresponding object ID and object details 224 for the part object. The design application 130 receives the second ML response 280 but does not yet display the object details 224 in the GUI 120. The design application 130 also stores the object details 224 received for each part object 810-864 in the assembly table 252. The user then selects the front rim part 842 and initiates the object detail function (e.g., via a second predetermined hotkey input). In response, the design application 130 retrieves the object details 224 for the selected front rim part 842 from the assembly table 252, and displays the object details 224 in the design space 230 adjacent to the selected front rim part 842.

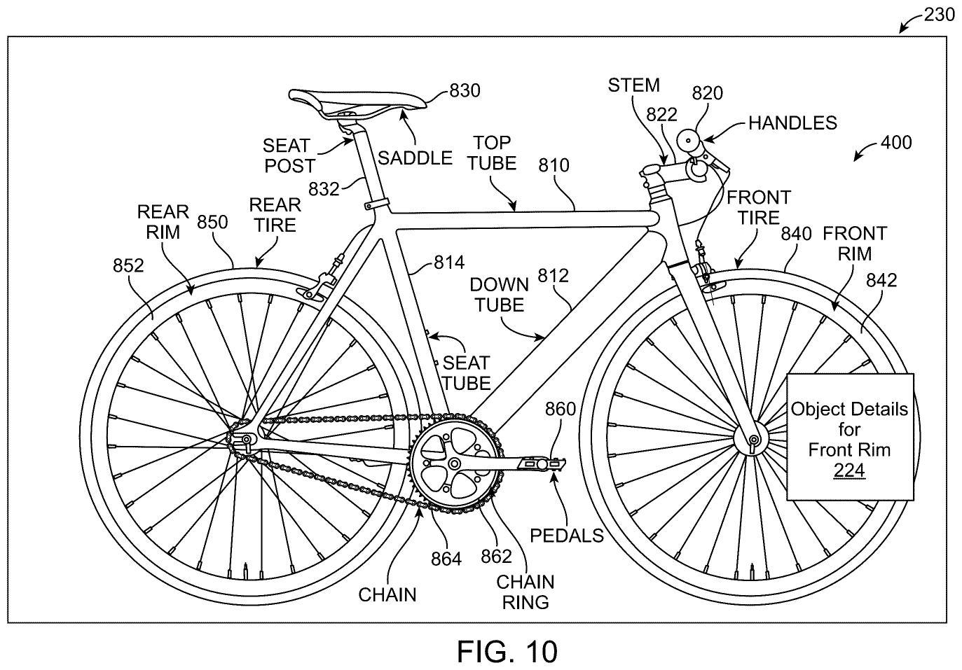

FIG. 10 is an exemplar illustration of the bike assembly 400 of FIG. 8 with part details, according to various embodiments. As shown, the design space 230 displays the bike assembly 400 with object details 224 for the front rim part 842 adjacent to the front rim part 842. In other embodiments, the object details 224 can be displayed in the prompt space 220. When the user moves the cursor away from the selected front rim part 842, the design application 130 no longer displays the object details 224 in the GUI 120.

Concurrently, as the server device 160 generates and transmits the first ML response 280 and the second ML response 280, the server device 160 can simultaneously implement one or more ML models 180, 190 to determine one or more object commands 226 associated with each part object 810-864 specified in second prompt 260. The server device 160 can then generate and transmit a third ML response 280 that includes, for each part object 810-864 specified in the second prompt 260, the corresponding object ID and object commands 226 for the part object. The design application 130 receives the third ML response 280 but does not yet display the object commands 226 in the GUI 120. The design application 130 also stores the object commands 226 received for each specified part object 810-864 in the assembly table 252. The user then selects the front rim part 842 and initiates the object command function (e.g., via a third predetermined hotkey input). In response, the design application 130 retrieves the object commands 226 for the selected front rim part 842 from the assembly table 252, and displays the object commands 226 in the design space 230 adjacent to the selected front rim part 842.

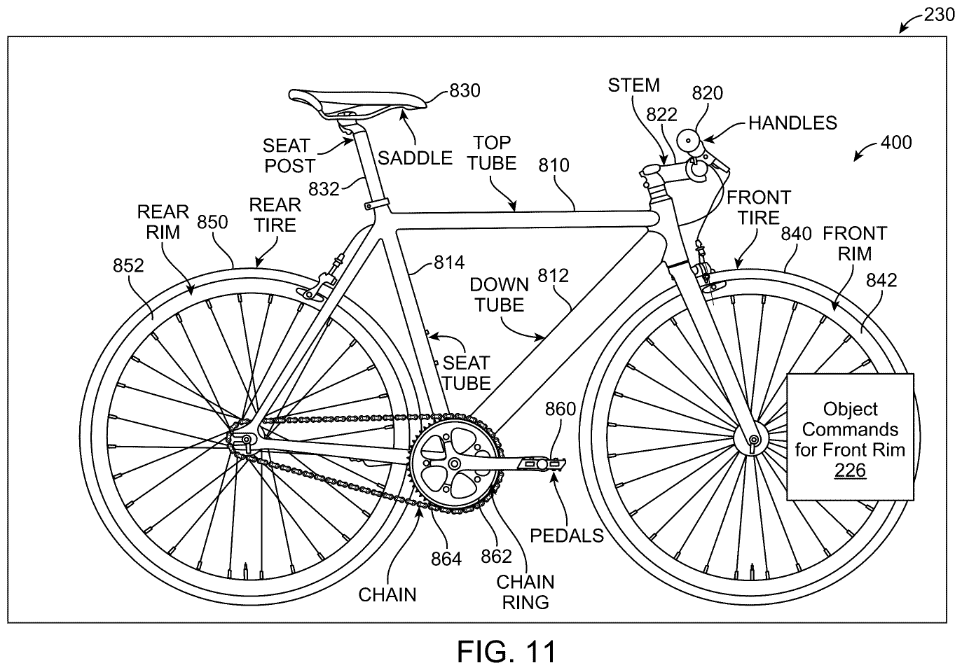

FIG. 11 is an exemplar illustration of the bike assembly 400 of FIG. 8 with part commands, according to various embodiments. As shown, the design space 230 displays the bike assembly 400 with object commands 226 for the front rim part 842 adjacent to the front rim part 842. In other embodiments, the object commands 226 can be displayed in the prompt space 220. When the user moves the cursor away from the selected front rim part 842, the design application 130 no longer displays the object commands 226 in the GUI 120.

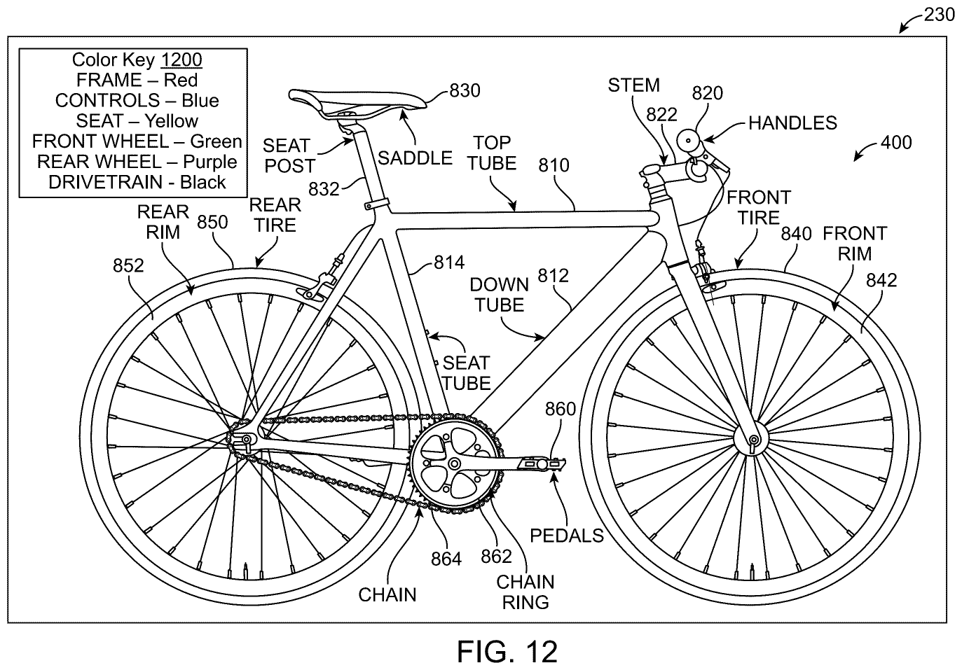

FIG. 12 is an exemplar illustration of the bike assembly 400 of FIG. 8 with a color key chart, according to various embodiments. In some embodiments, while in the second zoom-level range corresponding to part objects, the user can also initiate a sub-assembly color function (e.g., via a fourth predetermined hotkey input). In response, the design application 130 displays a color key chart 1200 in the design space 230 that specifies a different text color assigned to each sub-assembly object of the overall design (such as the bike assembly 400). The design application 130 then displays, for each sub-assembly object, the object labels 222 for the part objects contained in the sub-assembly object with the text color that is assigned to the particular sub-assembly object. For example, the frame sub-assembly 410 can include the top tube part 810, the down tube part 812, and the seat tube part 814. As shown, the frame sub-assembly 410 is assigned the text color of red in the color key chart 1200, and thus the object labels for the top tube part 810, the down tube part 812, and the seat tube part 814 are displayed with red text. Likewise, the controls sub-assembly 420 can include the handles part 820 and the stem part 822. As shown, the controls sub-assembly 420 is assigned the text color of blue in the color key chart 1200, and thus the object labels for the handles part 820 and the stem part 822 are displayed with blue text. Similar operations would also be performed on the seat sub-assembly 430, front wheel sub-assembly 440, rear wheel sub-assembly 450, and the drivetrain sub-assembly 460.

As the user continues to navigate and change zoom levels within the design space 230, the current zoom level can exit the second zoom-level range corresponding to part objects and enter the first or third zoom-level ranges. In some embodiments, when the current zoom level is no longer within the second zoom-level range, the design application 130 no longer displays the object labels 222 for the part objects within the design space 230. For example, the current zoom level can enter the third zoom-level range corresponding to element objects.

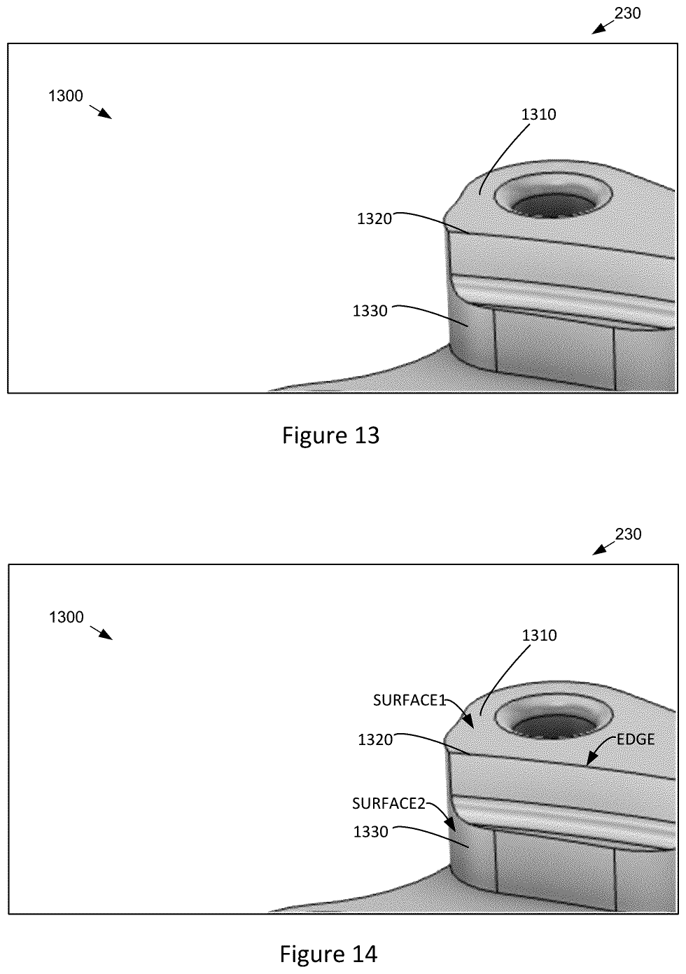

In this regard, FIGS. 13-16 illustrate an automated object-information feature/function for element objects. FIG. 13 is an exemplar illustration of a portion of a bike assembly 1300 shown at a third zoom level within the design space 230 of FIG. 2, according to various embodiments. As shown, the design space 230 displays the portion of the bike assembly 1300 comprising a plurality of element objects 144, including a first surface element 1310, an edge element 1320, and a second surface element 1330. In other embodiments, the portion of the bike assembly 1300 includes additional elements. However, for illustration clarity, not all possible elements of the portion of the bike assembly 1300 are shown.

The user initiates the object labelling function (e.g., via the first predetermined hotkey input), and in response, the design application 130 determines that the current zoom level comprises a third zoom level that is within the third zoom-level range corresponding to element objects. The design application 130 then generates a third prompt 260 comprising design intent text 262, design files 142, and design data 146. The design files 142 include geometries for all design objects 144 of the portion of the bike assembly 1300 currently displayed within the design space 230. The design data 146 includes a set of object IDs for only the element objects 1310-1330 (and not sub-assembly objects or part objects) within the portion of the bike assembly 1300, such as only those element objects 1310-1330 currently displayed in the design space 230. The design data 146 also includes a set of design application commands that were previously executed on the bike assembly 400. The design intent text 262 comprises a text query requesting object labels 222, object details 224, and/or object commands 226 associated with each element object 1310-1330 specified in the set of object IDs of the design data 146.

The design application 130 transmits the third prompt 260 to the server device 160, which implements one or more ML models 180, 190 to generate and return one or more ML responses 280 based on the third prompt 260. The server device 160 can then generate and transmit a first ML response 280 that includes, for each element object 1310-1330 specified in the third prompt 260, the corresponding object ID and object label 222 for the element object 1310-1330. The design application 130 receives the first ML response 280 and displays the object labels 222 in the design space 230 by displaying each object label 222 adjacent to the corresponding element object 1310-1330. The design application 130 also stores the object label 222 received for each element object 1310-1330 in the assembly table 252.

FIG. 14 is an exemplar illustration of the portion of the bike assembly 1300 of FIG. 13 with element object labels, according to various embodiments. As shown, the design space 230 displays the portion of the bike assembly 1300 with object labels adjacent to the corresponding element objects 1310-1330. As shown, the object label “SURFACE1” is displayed adjacent to the first surface element 1310, the object label “EDGE” is displayed adjacent to the edge element 1320, the object label “SURFACE2” is displayed adjacent to the second surface element 1330. In other embodiments, an object label 222 is not placed adjacent to the corresponding design object 144, but includes an indicator (such as an arrow) that points to the corresponding design object 144.

Concurrently, as the server device 160 generates and transmits the first ML response 280, the server device 160 can simultaneously implement one or more ML models 180, 190 to generate and transmit a second ML response 280 that includes, for each element object 1310-1330 specified in the third prompt 260, the corresponding object ID and object details 224 for the element object. The design application 130 receives the second ML response 280 but does not yet display the object details 224 in the GUI 120. The design application 130 also stores the object details 224 received for each element object 1310-1330 in the assembly table 252. The user then selects the second surface element 1330 and initiates the object detail function (e.g., via a second predetermined hotkey input). In response, the design application 130 retrieves the object details 224 for the selected second surface element 1330 from the assembly table 252, and displays the object details 224 in the design space 230 adjacent to the selected second surface element 1330.

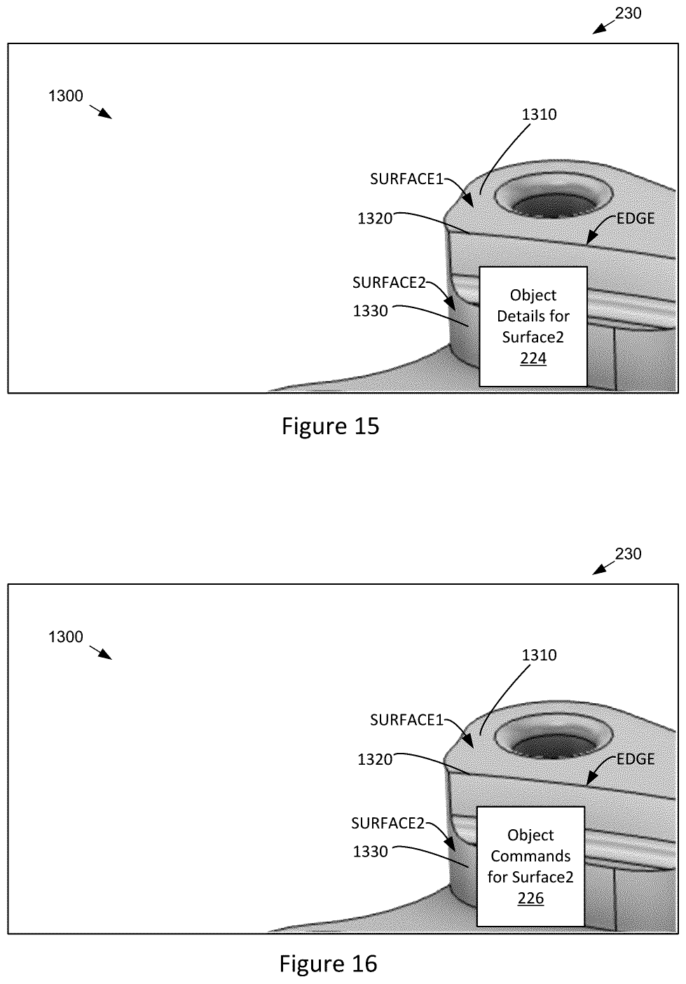

FIG. 15 is an exemplar illustration of the portion of the bike assembly 1300 of FIG. 13 with element details, according to various embodiments. As shown, the design space 230 displays the portion of the bike assembly 1300 with object details 224 for the second surface element 1330 adjacent to the second surface element 1330. In other embodiments, the object details 224 can be displayed in the prompt space 220. When the user moves the cursor away from the selected second surface element 1330, the design application 130 no longer displays the object details 224 in the GUI 120.

Concurrently, as the server device 160 generates and transmits the first ML response 280 and the second ML response 280, the server device 160 can simultaneously implement one or more ML models 180, 190 to determine one or more object commands 226 associated with each element object 1310-1330 specified in third prompt 260. The server device 160 can then generate and transmit a third ML response 280 that includes, for each element object 1310-1330 specified in the third prompt 260, the corresponding object ID and object commands 226 for the element object. The design application 130 receives the third ML response 280 but does not yet display the object commands 226 in the GUI 120. The design application 130 also stores the object commands 226 received for each specified element object 1310-1330 in the assembly table 252. The user then selects the second surface element 1330 and initiates the object command function (e.g., via a third predetermined hotkey input). In response, the design application 130 retrieves the object commands 226 for the selected second surface element 1330 from the assembly table 252, and displays the object commands 226 in the design space 230 adjacent to the selected second surface element 1330.

FIG. 16 is an exemplar illustration of the portion of the bike assembly 1300 of FIG. 13 with element commands, according to various embodiments. As shown, the design space 230 displays the portion of the bike assembly 1300 with object commands 226 for the second surface element 1330 adjacent to the second surface element 1330. In other embodiments, the object commands 226 can be displayed in the prompt space 220. When the user moves the cursor away from the selected second surface element 1330, the design application 130 no longer displays the object commands 226 in the GUI 120.

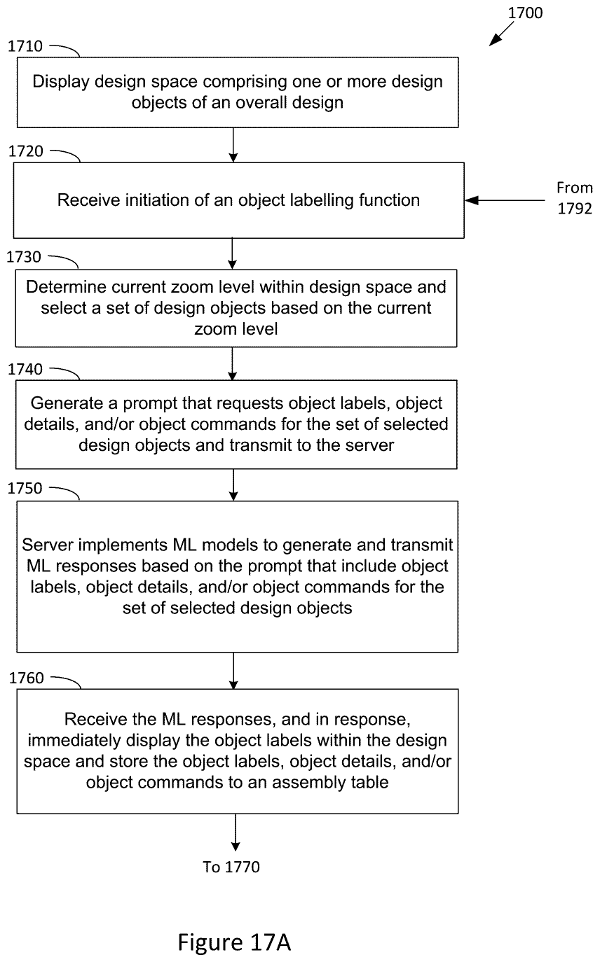

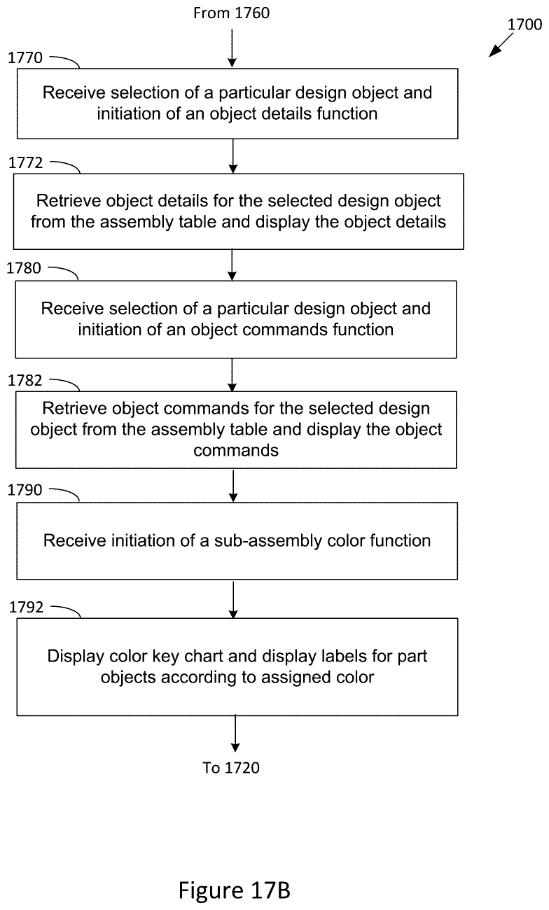

FIGS. 17A-B set forth a flow diagram of method steps for automatically retrieving and displaying object information for selected design objects within an overall design, according to various embodiments. Although the method steps are described with reference to the systems of FIGS. 1-16, persons skilled in the art will understand that any system configured to implement the method steps, in any order, falls within the scope of the embodiments. In some embodiments, a method 1700 is executed by the design application 130 and the various modules of the design application 130 to enable an object information feature/function within the design space 230.

As shown, the method 1700 begins at step 1710, where the design application 130 displays a GUI 120 comprising a design space 230. The design space 230 displays one or more design objects 144 of an overall design (assembly). The design exploration application 130 then receives (at step 1720) a user initiation of an object labelling function (e.g., via a first predetermined hotkey input). In response to receiving the user initiation of the object labelling function, the design exploration application 130 determines (at 1730) a current zoom level implemented within the design space 230 and selects a set of design objects 144 within the design space 230 based on the current zoom level. In response to receiving the user initiation of the object labelling function, the design exploration application 130 also generates (at 1740) a prompt 260 comprising design intent text 262, one or more design files 142, and/or design data 146 that queries/requests object information for the set of selected design objects 144 from one or more ML models 180, 190. The requested object information can include object labels 222, object details 224, and/or object commands 226 for the set of selected design objects 144. The design exploration application 130 also transmits (at 1740) the prompt 260 to the server device 160.

In response to receiving the prompt 260, the server device 160 implements the one or more ML models 180, 190 to generate (at 1750) one or more ML responses 280 based on the prompt 260. The one or more ML responses 280 include the requested object labels 222, object details 224, and/or object commands 226. The server device 160 also transmits (at 1750) the one or more ML responses 280 to the design exploration application 130. The design exploration application 130 receives (at 1760) the one or more ML responses, and in response, immediately displays the object labels 222 adjacent to the corresponding selected design objects 144 within the design space 230 and stores the object labels 222, object details 224, and/or object commands 226 for the set of selected design objects 144 to an assembly table 252 for the overall design (assembly).

The design exploration application 130 then receives (at 1770) a user selection of a particular design object 144 within the design space 230 and a user initiation of an object detail function (e.g., via a second predetermined hotkey input). In response, the design exploration application 130 retrieves (at 1772) the object details 224 corresponding to the selected design object 144 from the assembly table 252 and displays the object details 224 adjacent to the selected design object 144 within the design space 230 and/or the prompt space 260.

The design exploration application 130 then receives (at 1780) a user selection of a particular design object 144 within the design space 230 and a user initiation of an object command function (e.g., via a third predetermined hotkey input). In response, the design exploration application 130 retrieves (at 1782) the object commands 226 corresponding to the selected design object 144 from the assembly table 252 and displays the object commands 226 adjacent to the selected design object 144 within the design space 230 and/or the prompt space 260.

The design exploration application 130 then receives (at 1790) a user initiation of a sub-assembly color function (e.g., via a fourth predetermined hotkey input). In response, the design exploration application 130 displays (at 1792) a color key chart 1200 in the design space 230 that specifies a different text color assigned to each sub-assembly object of the overall design and displays, for each sub-assembly object, the object labels 222 for the part objects contained in the sub-assembly object with the text color that is assigned to the particular sub-assembly object. The method 1700 can then repeat at step 1720.

In some embodiments, the user can also submit a feedback prompt providing an evaluation indicating whether the received object labels 222, object details 224, and/or object commands 226 for a particular design object 144 are correct. For example, the follow-up prompt can specify that a particular object label 222 for a particular design object 144 is incorrect, particular object details 224 for a particular design object 144 is incorrect, and/or particular object commands 226 associated with a particular design object 144 are incorrect. The server device 160 can then store to the design history 182 the particular design object 144 and the feedback prompt(s) for the particular design object 144 as additional training data for retraining the one or more ML models 180, 190 for improving the accuracy of the one or more ML models 180, 190 in identifying object labels 222, object details 224, and/or object commands 226 for design objects 144.

### System Implementation

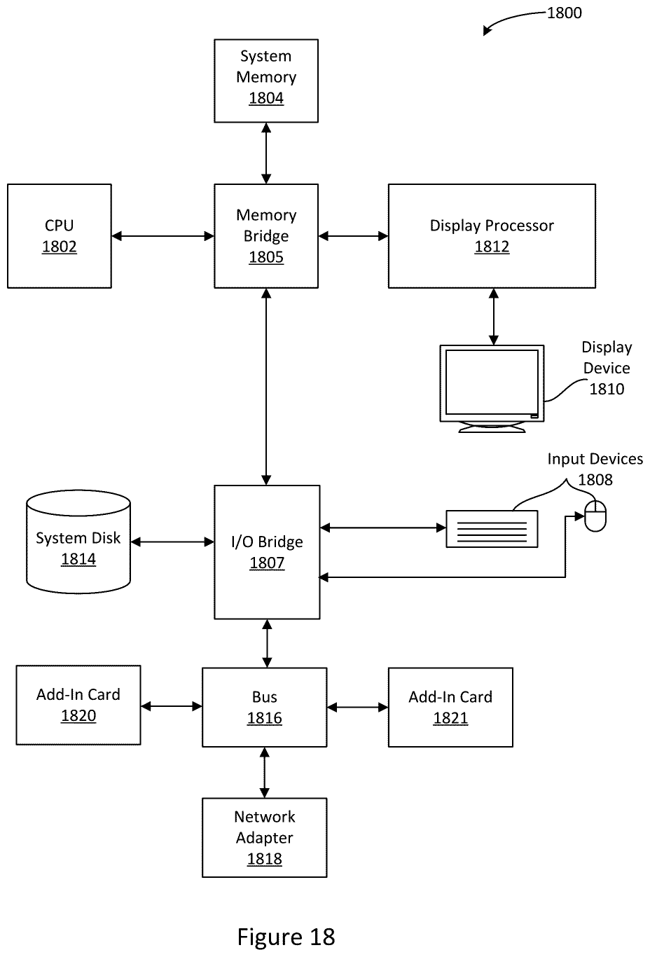

FIG. 18 depicts one architecture of a system within which one or more aspects of the various embodiments may be implemented. In some embodiments, the client device 110 and the server device 160 of FIG. 1 can each be implemented as a system 1800 described herein. This figure in no way limits or is intended to limit the scope of the present disclosure. In various implementations, system 1800 may be an augmented reality, virtual reality, or mixed reality system or device, a personal computer, video game console, personal digital assistant, mobile phone, mobile device, or any other device suitable for practicing one or more embodiments of the present disclosure. Further, in various embodiments, any combination of two or more systems 1800 may be coupled together to practice one or more aspects of the present disclosure.

As shown, system 1800 includes a central processing unit (CPU) 1802 and a system memory 1804 communicating via a bus path that may include a memory bridge 1805. CPU 1802 includes one or more processing cores, and, in operation, CPU 1802 is the master processor of system 1800, controlling and coordinating operations of other system components. System memory 1804 stores software applications and data for use by CPU 1802. CPU 1802 runs software applications and optionally an operating system. Memory bridge 1805, which may be, e.g., a Northbridge chip, is connected via a bus or other communication path (e.g., a HyperTransport link) to an I/O (input/output) bridge 1807. I/O bridge 1807, which may be, e.g., a Southbridge chip, receives user input from one or more user input devices 1808 (e.g., keyboard, mouse, joystick, digitizer tablets, touch pads, touch screens, still or video cameras, motion sensors, and/or microphones) and forwards the input to CPU 1802 via memory bridge 1805.

A display processor 1812 is coupled to memory bridge 1805 via a bus or other communication path (e.g., a PCI Express, Accelerated Graphics Port, or HyperTransport link); in one embodiment display processor 1812 is a graphics subsystem that includes at least one graphics processing unit (GPU) and graphics memory. Graphics memory includes a display memory (e.g., a frame buffer) used for storing pixel data for each pixel of an output image. Graphics memory can be integrated in the same device as the GPU, connected as a separate device with the GPU, and/or implemented within system memory 1804.

Display processor 1812 periodically delivers pixels to a display device 1810 (e.g., a screen or conventional CRT, plasma, OLED, SED or LCD based monitor or television). Additionally, display processor 1812 may output pixels to film recorders adapted to reproduce computer generated images on photographic film. Display processor 1812 can provide display device 1810 with an analog or digital signal. In various embodiments, one or more of the various graphical user interfaces set forth in Appendices A-J, attached hereto, are displayed to one or more users via display device 1810, and the one or more users can input data into and receive visual output from those various graphical user interfaces.

A system disk 1814 is also connected to I/O bridge 1807 and may be configured to store content and applications and data for use by CPU 1802 and display processor 1812. System disk 1814 provides non-volatile storage for applications and data and may include fixed or removable hard disk drives, flash memory devices, and CD-ROM, DVD-ROM, Blu-ray, HD-DVD, or other magnetic, optical, or solid state storage devices.

A switch 1816 provides connections between I/O bridge 1807 and other components such as a network adapter 1818 and various add-in cards 1820 and 1821. Network adapter 1818 allows system 1800 to communicate with other systems via an electronic communications network, and may include wired or wireless communication over local area networks and wide area networks such as the Internet.

Other components (not shown), including USB or other port connections, film recording devices, and the like, may also be connected to I/O bridge 1807. For example, an audio processor may be used to generate analog or digital audio output from instructions and/or data provided by CPU 1802, system memory 1804, or system disk 1814. Communication paths interconnecting the various components in FIG. 1 may be implemented using any suitable protocols, such as PCI (Peripheral Component Interconnect), PCI Express (PCI-E), AGP (Accelerated Graphics Port), HyperTransport, or any other bus or point-to-point communication protocol(s), and connections between different devices may use different protocols, as is known in the art.

In one embodiment, display processor 1812 incorporates circuitry optimized for graphics and video processing, including, for example, video output circuitry, and constitutes a graphics processing unit (GPU). In another embodiment, display processor 1812 incorporates circuitry optimized for general purpose processing. In yet another embodiment, display processor 1812 may be integrated with one or more other system elements, such as the memory bridge 1805, CPU 1802, and I/O bridge 1807 to form a system on chip (SoC). In still further embodiments, display processor 1812 is omitted and software executed by CPU 1802 performs the functions of display processor 1812.

Pixel data can be provided to display processor 1812 directly from CPU 1802. In some embodiments of the present disclosure, instructions and/or data representing a scene are provided to a render farm or a set of server computers, each similar to system 1800, via network adapter 1818 or system disk 1814. The render farm generates one or more rendered images of the scene using the provided instructions and/or data. These rendered images may be stored on computer-readable media in a digital format and optionally returned to system 1800 for display. Similarly, stereo image pairs processed by display processor 1812 may be output to other systems for display, stored in system disk 1814, or stored on computer-readable media in a digital format.

Alternatively, CPU 1802 provides display processor 1812 with data and/or instructions defining the desired output images, from which display processor 1812 generates the pixel data of one or more output images, including characterizing and/or adjusting the offset between stereo image pairs. The data and/or instructions defining the desired output images can be stored in system memory 1804 or graphics memory within display processor 1812. In an embodiment, display processor 1812 includes 3D rendering capabilities for generating pixel data for output images from instructions and data defining the geometry, lighting shading, texturing, motion, and/or camera parameters for a scene. Display processor 1812 can further include one or more programmable execution units capable of executing shader programs, tone mapping programs, and the like.

Further, in other embodiments, CPU 1802 or display processor 1812 may be replaced with or supplemented by any technically feasible form of processing device configured process data and execute program code. Such a processing device could be, for example, a central processing unit (CPU), a graphics processing unit (GPU), an application-specific integrated circuit (ASIC), a field-programmable gate array (FPGA), and so forth. In various embodiments any of the operations and/or functions described herein can be performed by CPU 1802, display processor 1812, or one or more other processing devices or any combination of these different processors.

CPU 1802, render farm, and/or display processor 1812 can employ any surface or volume rendering technique known in the art to create one or more rendered images from the provided data and instructions, including rasterization, scanline rendering REYES or micropolygon rendering, ray casting, ray tracing, image-based rendering techniques, and/or combinations of these and any other rendering or image processing techniques known in the art.

In other contemplated embodiments, system 1800 may be a robot or robotic device and may include CPU 1802 and/or other processing units or devices and system memory 1804. In such embodiments, system 1800 may or may not include other elements shown in FIG. 1. System memory 1804 and/or other memory units or devices in system 1800 may include instructions that, when executed, cause the robot or robotic device represented by system 1800 to perform one or more operations, steps, tasks, or the like.

It will be appreciated that the system shown herein is illustrative and that variations and modifications are possible. The connection topology, including the number and arrangement of bridges, may be modified as desired. For instance, in some embodiments, system memory 1804 is connected to CPU 1802 directly rather than through a bridge, and other devices communicate with system memory 1804 via memory bridge 1805 and CPU 1802. In other alternative topologies display processor 1812 is connected to I/O bridge 1807 or directly to CPU 1802, rather than to memory bridge 1805. In still other embodiments, I/O bridge 1807 and memory bridge 1805 might be integrated into a single chip. The particular components shown herein are optional; for instance, any number of add-in cards or peripheral devices might be supported. In some embodiments, switch 1816 is eliminated, and network adapter 1818 and add-in cards 1820, 1821 connect directly to I/O bridge 1807.

In sum, the disclosed techniques can be used to automatically provide various content for an ML model prompt by automatically entering content inputs into a prompt space or by directly generating the ML model prompt with the various content. In these embodiments, the design application 130 automatically generates one or more prompts in response to the user triggering/initiating an object labelling function (e.g., via a first predetermined hotkey input), and the transmits the one or more prompts 260 to the server device. Each prompt 260 can include design intent text 262, one or more design files 142, and/or design data 146. The design intent text 262 can include one or more text requests/queries for various objection information for selected design objects 144, the one or more design files 142 can include geometries for one or more design objects 144, and the design data 146 can include object IDs for the selected design objects 144 and/or design application commands that were executed on the overall design. The server device 160 then implements one or more ML models 180, 190 to generate and return one or more ML responses 280 based on the one or more prompts 260.

In general, the one or more prompts 260 requests/queries for various object information (labels, details, and commands) associated with one or more selected design objects 144 of the overall design displayed in the design space 230. The object information returned in the one or more ML responses 280 can comprise object labels 222, object details 224, and/or object commands 226 for one or more selected design objects 144 of the overall design. The overall design (assembly) can include one or more sub-assembly objects, each sub-assembly object comprising one or more part objects, and each part object comprising one or more element objects (geometric primitives). The one or more selected design objects 144 of the overall design can be selected based on a current zoom level corresponding to a sub-assembly object level, part object level, or element object level.

At least one technical advantage of the disclosed techniques relative to the prior art is that the disclosed techniques can be used to automatically generate and display a wide variety of object information associated with one or more design objects included in an overall design (assembly) via one or more ML models. For each design object, the displayed object information can include an object label that identifies a specific type of sub-assembly, part, or element that the design object represents, additional detailed information (including alternative geometries) for the design object, and/or a set of design application commands that were executed to generate and/or modify the design object. As such, the disclosed techniques instantly label and provide further insight into the different design objects of the assembly. By automatically providing different levels of object information (labels, additional details, and associated commands) for the design objects of an assembly, the disclosed techniques allow a user to quickly and easily gain different levels of understanding about the design objects of the assembly. In addition, the disclosed techniques allow a user without any prior exposure to or experience with a particular assembly to better and more quickly understand the assembly and the objects making up the assembly, thereby enabling the user to review and/or contribute to a design project involving the assembly more readily and easily. These technical advantages provide one or more technological advancements over prior art approaches.

Aspects of the subject matter described herein are set out in the following numbered clauses.

1. In some embodiments, a computer-implemented method for displaying object information associated with a computer-aided design comprises displaying a design space that includes a plurality of design objects, generating a prompt that includes a set of object identifiers corresponding to a first set of design objects included in the plurality of design objects and a first query for a set of object labels corresponding to the first set of design objects, transmitting the prompt to at least one trained machine learning (ML) model for processing, receiving, from the at least one trained ML model, a first ML response that includes the set of object labels corresponding to the first set of design objects, and displaying the set of object labels within the design space.

2. The computer-implemented method of clause 1, further comprising selecting the first set of design objects from the plurality of design objects based on a current zoom level within the design space.

3. The computer-implemented method of clauses 1 or 2, wherein a current zoom level within the design space corresponds to a sub-assembly level, and the first set of design objects comprises one or more sub-assembly objects included in the plurality of design objects.

4. The computer-implemented method of any of clauses 1-3, wherein a current zoom level within the design space corresponds to a part level, and the first set of design objects comprises one or more part objects included in the plurality of design objects.

5. The computer-implemented method of any of clauses 1-4, wherein a current zoom level within the design space corresponds to an element level, and the first set of design objects comprises one or more element objects included in the plurality of design objects.

6. The computer-implemented method of any of clauses 1-5, wherein the prompt further includes a second query for a set of object details corresponding to the first set of design objects, and further comprising receiving, from the at least one trained ML model, a second ML response comprising the set of object details corresponding to the first set of design objects, receiving an initiation of an object details function for a first design object included in the first set of design objects, and displaying a first subset of object details included in the set of object details and corresponding to the first design object within at least one of the design space or a prompt space.

7. The computer-implemented method of any of clauses 1-6, wherein the first subset of object details corresponding to the first design object includes at least one of an alternative geometry for the first design object, manufacturing information associated with first design object, or a technical definition of the first design object.

8. The computer-implemented method of any of clauses 1-7, wherein the prompt further includes a set of design commands that were executed on the overall design and a third query for a set of object commands corresponding to the first set of design objects, and further comprising receiving, from the at least one trained ML model, a second ML response comprising the set of object commands corresponding to the first set of design objects, receiving an initiation of an object commands function for a first design object included in the first set of design objects, and displaying a first subset of object commands included in the set of object commands and corresponding to the first design object within at least one of the design space or a prompt space.

9. The computer-implemented method of any of clauses 1-8, wherein the first subset of object commands corresponding to the first design object includes one or more design commands included in the set of design commands that are associated with the first design object.

10. The computer-implemented method of any of clauses 1-9, wherein the set of object identifiers corresponding to the first set of design objects are parsed from metadata associated with the first set of design objects.

11. In some embodiments, one or more non-transitory computer-readable media include instructions that, when executed by one or more processors, cause the one or more processors to display object information associated with a computer-aided design by performing the steps of displaying a design space that includes a plurality of design objects, generating a prompt that includes a set of object identifiers corresponding to a first set of design objects included in the plurality of design objects and a first query for a set of object labels corresponding to the first set of design objects, transmitting the prompt to at least one trained machine learning (ML) model for processing, receiving, from the at least one trained ML model, a first ML response that includes the set of object labels corresponding to the first set of design objects, and displaying the set of object labels within the design space.

12. The one or more non-transitory computer-readable media of clause 11, further comprising selecting the first set of design objects from the plurality of design objects based on a current zoom level within the design space.

13. The one or more non-transitory computer-readable media of clauses 11 or 12, wherein a current zoom level within the design space corresponds to a sub-assembly level, the first set of design objects comprises all sub-assembly objects included in the plurality of design objects that are currently displayed within the design space.

14. The one or more non-transitory computer-readable media of any of clauses 11-13, wherein a current zoom level within the design space corresponds to a part level, and the first set of design objects comprises all part objects included in the plurality of design objects that are currently displayed within the design space.

15. The one or more non-transitory computer-readable media of any of clauses 11-14, wherein a current zoom level within the design space corresponds to an element level, and the first set of design objects comprises all element objects included in the plurality of design objects that are currently displayed within the design space.

16. The one or more non-transitory computer-readable media of any of clauses 11-15, wherein the prompt further includes a second query for a set of object details corresponding to the first set of design objects, and further comprising receiving, from the at least one trained ML model, a second ML response comprising the set of object details corresponding to the first set of design objects, receiving an initiation of an object details function for a first design object included in the first set of design objects, and displaying a first subset of object details included in the set of object details and corresponding to the first design object within at least one of the design space or a prompt space.

17. The one or more non-transitory computer-readable media of any of clauses 11-16, wherein the first subset of object details corresponding to the first design object includes at least one of an alternative geometry for the first design object, manufacturing information associated with first design object, or a technical definition of the first design object.

18. The one or more non-transitory computer-readable media of any of clauses 11-17, wherein the prompt further includes a set of design commands that were executed on the overall design and a third query for a set of object commands corresponding to the first set of design objects, and further comprising receiving, from the at least one trained ML model, a second ML response comprising the set of object commands corresponding to the first set of design objects, receiving an initiation of an object commands function for a first design object included in the first set of design objects, and displaying a first subset of object commands included in the set of object commands and corresponding to the first design object within at least one of the design space or a prompt space.

19. The one or more non-transitory computer-readable media of any of clauses 11-18, wherein the first subset of object commands corresponding to the first design object includes one or more design commands included in the set of design commands that are associated with the first design object.

20. In some embodiments, a system comprises one or more memories storing instructions, and one or more processors coupled to the one or more memories that, when executing the instructions, perform the steps of displaying a design space that includes a plurality of design objects, generating a prompt that includes a set of object identifiers corresponding to a first set of design objects included in the plurality of design objects and a first query for a set of object labels corresponding to the first set of design objects, transmitting the prompt to at least one trained machine learning (ML) model for processing, receiving, from the at least one trained ML model, a first ML response that includes the set of object labels corresponding to the first set of design objects, and displaying the set of object labels within the design space.

Any and all combinations of any of the claim elements recited in any of the claims and/or any elements described in this application, in any fashion, fall within the contemplated scope of the present disclosure and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments can be embodied as a system, method or computer program product. Accordingly, aspects of the present disclosure can take the form of an entirely hardware embodiment, an entirely software embodiment (including firmware, resident software, micro-code, etc.) or an embodiment combining software and hardware aspects that can all generally be referred to herein as a “module” or “system.” In addition, any hardware and/or software technique, process, function, component, engine, module, or system described in the present disclosure can be implemented as a circuit or set of circuits. Furthermore, aspects of the present disclosure can take the form of a computer program product embodied in one or more computer readable medium(s) having computer readable program code embodied thereon. The software constructs and entities (e.g., engines, modules, GUIs, etc.) are, in various embodiments, stored in the memory/memories shown in the relevant system figure(s) and executed by the processor(s) shown in those same system figures.

Any combination of one or more non-transitory computer readable medium or media may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the preceding is directed to embodiments of the present disclosure, other and further embodiments of the disclosure may be devised without departing from the basic scope thereof, and the scope thereof is determined by the claims that follow.

What is claimed is:

1. A computer-implemented method for displaying object information associated with a computer-aided design, the method comprising:
displaying a design space that includes a plurality of design objects;
generating a prompt that includes a set of object identifiers corresponding to a first set of design objects included in the plurality of design objects and a first query for a set of object labels corresponding to the first set of design objects;
transmitting the prompt to at least one trained machine learning (ML) model for processing;
receiving, from the at least one trained ML model, a first ML response that includes the set of object labels corresponding to the first set of design objects; and
displaying the set of object labels within the design space.

2. The computer-implemented method of claim 1, further comprising selecting the first set of design objects from the plurality of design objects based on a current zoom level within the design space.

3. The computer-implemented method of claim 1, wherein a current zoom level within the design space corresponds to a sub-assembly level, and the first set of design objects comprises one or more sub-assembly objects included in the plurality of design objects.

4. The computer-implemented method of claim 1, wherein a current zoom level within the design space corresponds to a part level, and the first set of design objects comprises one or more part objects included in the plurality of design objects.

5. The computer-implemented method of claim 1, wherein a current zoom level within the design space corresponds to an element level, and the first set of design objects comprises one or more element objects included in the plurality of design objects.

6. The computer-implemented method of claim 1, wherein the prompt further includes a second query for a set of object details corresponding to the first set of design objects, and further comprising:
receiving, from the at least one trained ML model, a second ML response comprising the set of object details corresponding to the first set of design objects;
receiving an initiation of an object details function for a first design object included in the first set of design objects; and
displaying a first subset of object details included in the set of object details and corresponding to the first design object within at least one of the design space or a prompt space.

7. The computer-implemented method of claim 6, wherein the first subset of object details corresponding to the first design object includes at least one of an alternative geometry for the first design object, manufacturing information associated with first design object, or a technical definition of the first design object.

8. The computer-implemented method of claim 1, wherein the prompt further includes a set of design commands that were executed on the overall design and a third query for a set of object commands corresponding to the first set of design objects, and further comprising:
receiving, from the at least one trained ML model, a second ML response comprising the set of object commands corresponding to the first set of design objects;
receiving an initiation of an object commands function for a first design object included in the first set of design objects; and
displaying a first subset of object commands included in the set of object commands and corresponding to the first design object within at least one of the design space or a prompt space.

9. The computer-implemented method of claim 8, wherein the first subset of object commands corresponding to the first design object includes one or more design commands included in the set of design commands that are associated with the first design object.

10. The computer-implemented method of claim 1, wherein the set of object identifiers corresponding to the first set of design objects are parsed from metadata associated with the first set of design objects.

11. One or more non-transitory computer-readable media including instructions that, when executed by one or more processors, cause the one or more processors to display object information associated with a computer-aided design by performing the steps of:
displaying a design space that includes a plurality of design objects;
generating a prompt that includes a set of object identifiers corresponding to a first set of design objects included in the plurality of design objects and a first query for a set of object labels corresponding to the first set of design objects;
transmitting the prompt to at least one trained machine learning (ML) model for processing;
receiving, from the at least one trained ML model, a first ML response that includes the set of object labels corresponding to the first set of design objects; and
displaying the set of object labels within the design space.

12. The one or more non-transitory computer-readable media of claim 11, further comprising selecting the first set of design objects from the plurality of design objects based on a current zoom level within the design space.

13. The one or more non-transitory computer-readable media of claim 11, wherein a current zoom level within the design space corresponds to a sub-assembly level, the first set of design objects comprises all sub-assembly objects included in the plurality of design objects that are currently displayed within the design space.

14. The one or more non-transitory computer-readable media of claim 11, wherein a current zoom level within the design space corresponds to a part level, and the first set of design objects comprises all part objects included in the plurality of design objects that are currently displayed within the design space.

15. The one or more non-transitory computer-readable media of claim 11, wherein a current zoom level within the design space corresponds to an element level, and the first set of design objects comprises all element objects included in the plurality of design objects that are currently displayed within the design space.

16. The one or more non-transitory computer-readable media of claim 11, wherein the prompt further includes a second query for a set of object details corresponding to the first set of design objects, and further comprising:
receiving, from the at least one trained ML model, a second ML response comprising the set of object details corresponding to the first set of design objects;
receiving an initiation of an object details function for a first design object included in the first set of design objects; and
displaying a first subset of object details included in the set of object details and corresponding to the first design object within at least one of the design space or a prompt space.

17. The one or more non-transitory computer-readable media of claim 16, wherein the first subset of object details corresponding to the first design object includes at least one of an alternative geometry for the first design object, manufacturing information associated with first design object, or a technical definition of the first design object.

18. The one or more non-transitory computer-readable media of claim 11, wherein the prompt further includes a set of design commands that were executed on the overall design and a third query for a set of object commands corresponding to the first set of design objects, and further comprising:
receiving, from the at least one trained ML model, a second ML response comprising the set of object commands corresponding to the first set of design objects;
receiving an initiation of an object commands function for a first design object included in the first set of design objects; and
displaying a first subset of object commands included in the set of object commands and corresponding to the first design object within at least one of the design space or a prompt space.

19. The one or more non-transitory computer-readable media of claim 18, wherein the first subset of object commands corresponding to the first design object includes one or more design commands included in the set of design commands that are associated with the first design object.

20. A system comprising:
one or more memories storing instructions; and
one or more processors coupled to the one or more memories that, when executing the instructions, perform the steps of:
displaying a design space that includes a plurality of design objects;
generating a prompt that includes a set of object identifiers corresponding to a first set of design objects included in the plurality of design objects and a first query for a set of object labels corresponding to the first set of design objects;
transmitting the prompt to at least one trained machine learning (ML) model for processing;
receiving, from the at least one trained ML model, a first ML response that includes the set of object labels corresponding to the first set of design objects; and
displaying the set of object labels within the design space.
